(19) United States
(12) Patent Application Publication
(10) Pub. No.: US 2016/0374205 A1
(43) Pub. Date: Dec. 22, 2016

(54) COPPER FOIL WITH CARRIER, LAMINATE, METHOD OF PRODUCING PRINTED WIRING BOARD, AND METHOD OF PRODUCING ELECTRONIC DEVICES

(71) Applicant: JX NIPPON MINING & METALS CORPORATION, Tokyo (JP)

(72) Inventors: TERUMASA MORIYAMA, IBARAKI (JP); YOSHIYUKI MIYOSHI, IBARAKI (JP); TOMOTA NAGAURA, IBARAKI (JP); MICHIYA KOHIKI, IBARAKI (JP)

(21) Appl. No.: 15/181,867

(22) Filed: Jun. 14, 2016

(30) Foreign Application Priority Data
Jun. 17, 2015 (JP) 2015-122457
Feb. 18, 2016 (JP) 2016-029305

(51) Int. Cl. H05K 3/00; H05K 1/02; B32B 15/08; B32B 38/10; B32B 37/14; H05K 1/09; H05K 3/46

(52) U.S. Cl. CPC H05K 3/007; H05K 1/09; H05K 1/0298; H05K 3/4658; H05K 3/4682; B32B 38/10; B32B 37/14; B32B 15/08; B32B 2457/08

(57) ABSTRACT

The present invention provides a copper foil with a carrier having a small absolute value of the difference in releasing strength between the copper foil with a carrier prepared by laminating and hot-pressing the surface close to an ultra-thin copper layer of the copper foil with a carrier to an insulating substrate and used after the carrier is peeled off and the copper foil with a carrier prepared by laminating and hot-pressing the surface close to the carrier of the copper foil with a carrier to an insulating substrate and used after the ultra-thin copper layer is peeled off, while generation of swelling during laminating of the copper foil with a carrier to the insulating substrate by hot pressing is prevented, discoloring of the surface of the ultra-thin copper layer due to oxidation is prevented, and the circuit formability is high. A copper foil with a carrier, including a carrier, an intermediate layer, an ultra-thin copper layer, and a surface treated layer in this order, wherein no roughened layer is disposed on the surface of the ultra-thin copper layer, and the surface treated layer consists of Zn or a Zn alloy, the amount of Zn applied in the surface treated layer is 30 to 300 μg/dm², and if the surface treated layer is composed of the Zn alloy, the proportion of Zn in the Zn alloy is 51% by mass or more.

### BACKGROUND OF THE INVENTION

Field of the Invention

The present invention relates to copper foils with a carrier, laminates, methods of producing printed wiring boards, and methods of producing electronic devices.

Description of the Related Art

Printed wiring boards are usually produced through the following process: an insulating substrate is bonded onto a copper foil to prepare a copper clad laminate board, and the surface of the copper foil is then etched into a conductive pattern. Recent needs for miniaturization of electronic devices and an increase in their performance have promoted an increase in packaging density of components mounted on these devices and an increase in frequency of signals. Thus, printed wiring boards should satisfy requirements such as a further reduction in pitch of the conductive pattern (finer pitches) and an increase in frequency of signals.

For finer pitches, copper foils having a thickness of 9 μm or less, or 5 μm or less have recently been required. Such extremely thin copper foils have low mechanical strength to readily break or wrinkle during production of printed wiring boards. Accordingly, a copper foil with a carrier, wherein a thick metal foil is adopted as the carrier and an ultra-thin copper layer is electrodeposited on the carrier via a releasing layer between them, has been proposed. The surface of the ultra-thin copper layer is laminated and hot-pressed to an insulating substrate and then the carrier is peeled off via the releasing layer. A circuit pattern is formed on the exposed ultra-thin copper layer with a resist to form a predetermined circuit (for example, WO2004/005588).

The copper foil with a carrier is classified into two types: One is those prepared by laminating and hot-pressing the surface close to the ultra-thin copper layer of the copper foil with a carrier to an insulating substrate, as described above. This type of the copper foil with a carrier is used after the carrier is peeled off. The other is those prepared by laminating and hot-pressing the surface close to the carrier of the copper foil with a carrier to an insulating substrate. This type is used after the ultra-thin copper layer is peeled off. Both types preferably have releasing strength desired by users. Unfortunately, desired releasing strength may not be satisfied in those prepared by laminating and hot-pressing the surface close to the ultra-thin copper layer of the copper foil with a carrier to an insulating substrate and used after the carrier is peeled off, and those prepared by laminating and hot-pressing the surface close to the carrier of the copper foil with a carrier to an insulating substrate and used after the ultra-thin copper layer is peeled off.

The copper foil with a carrier is hot-pressed to the insulating substrate when laminated thereto. During this process, a gas, such as steam, generated between the carrier and the ultra-thin copper layer may generate air bubbles (swelling). If such swelling is generated, the ultra-thin copper layer used in formation of a circuit is depressed, adversely affecting circuit formability.

Furthermore, the surface of the ultra-thin copper layer is discolored due to oxidation during laminating of the surface close to the carrier of the copper foil with a carrier to the insulating substrate by hot pressing.

An object of the present invention is to provide a copper foil with a carrier having a small absolute value of the difference in releasing strength between the copper foil with a carrier prepared by laminating and hot-pressing the surface close to an ultra-thin copper layer of the copper foil with a carrier to an insulating substrate and used after the carrier is peeled off and the copper foil with a carrier prepared by laminating and hot-pressing the surface close to the carrier of the copper foil with a carrier to an insulating substrate and used after the ultra-thin copper layer is peeled off, while generation of swelling during laminating of the copper foil with a carrier to the insulating substrate by hot pressing is prevented, discoloring of the surface of the ultra-thin copper layer due to oxidation is preferably prevented, and the circuit formability is high.

### SUMMARY OF THE INVENTION

The present inventors, who have conducted extensive research to achieve the above-mentioned goal, have found the following: When a surface treated layer is formed on the surface of the ultra-thin copper layer of a copper foil with a carrier without a roughened layer being disposed, the surface treated layer is composed of Zn or a Zn alloy, an amount of Zn applied in the surface treated layer is controlled in a predetermined range, and if the surface treated layer is composed of the Zn alloy, the proportion of Zn in the Zn alloy is controlled in a predetermined range, a copper foil with a carrier can be provided which has a small absolute value of the difference in releasing strength between the copper foil with a carrier prepared by laminating and hot-pressing the surface close to the ultra-thin copper layer of the copper foil with a carrier to an insulating substrate and used after the carrier is peeled off and the copper foil with a carrier prepared by laminating and hot-pressing the surface close to the carrier of the copper foil with a carrier to an insulating substrate and used after the ultra-thin copper layer is peeled off, while generation of swelling during laminating of the copper foil with a carrier to the insulating substrate by hot pressing is prevented, discoloring of the surface of the ultra-thin copper layer due to oxidation is preferably prevented, and the circuit formability is high.

The present invention has been completed based on the above knowledge. One aspect according to the present invention is a copper foil with a carrier, including a carrier, an intermediate layer, an ultra-thin copper layer, and a surface treated layer in this order, wherein no roughened layer is disposed on the surface of the ultra-thin copper layer, and the surface treated layer consists of Zn or a Zn alloy, the amount of Zn applied in the surface treated layer is 30 to 300 μg/dm², and if the surface treated layer is composed of the Zn alloy, the proportion of Zn in the Zn alloy is 51% by mass or more.

In one embodiment of the copper foil with a carrier according to the present invention, the Zn alloy comprises Zn and one or more elements selected from the group consisting of Ni, Co, Cu, Mo, and Mn.

In another embodiment of the copper foil with a carrier according to the present invention, the Zn alloy consists of Zn and one or more elements selected from the group consisting of Ni, Co, Cu, Mo, and Mn.

In further another embodiment of the copper foil with a carrier according to the present invention, the surface treated layer is composed of a Zn alloy consisting of Zn and one or more elements selected from the group consisting of Co and Ni, and the proportion of Zn in the surface treated layer is 51% by mass or more and less than 100% by mass.

In yet another embodiment of the copper foil with a carrier according to the present invention, the surface treated layer is composed of a Zn alloy consisting of Zn and Co, and the proportion of Zn in the surface treated layer is 51% by mass or more and less than 100% by mass.

In yet another embodiment of the copper foil with a carrier according to the present invention, the surface treated layer is composed of a Zn alloy consisting of Zn and Ni, and the proportion of Zn in the surface treated layer is 51% by mass or more and less than 100% by mass.

In yet another embodiment of the copper foil with a carrier according to the present invention, the surface close to the ultra-thin copper layer of the copper foil with a carrier has a surface roughness Rz of 0.1 to 2.0 μm.

In yet another embodiment of the copper foil with a carrier according to the present invention, the carrier has a thickness of 5 to 500 μm.

In yet another embodiment of the copper foil with a carrier according to the present invention, the ultra-thin copper layer has a thickness of 0.01 to 12 μm.

In yet another embodiment of the copper foil with a carrier according to the present invention, if the ultra-thin copper layer is disposed on one surface of the carrier in the copper foil with a carrier, one or more layers selected from the group consisting of a chromate treated layer and a silane coupling treated layer are disposed between the ultra-thin copper layer and the surface treated layer,

or if the ultra-thin copper layer is disposed on both surfaces of the carrier in the copper foil with a carrier and the surface treated layer is disposed on the ultra-thin copper layer on at least one of both surfaces, one or more layers selected from the group consisting of a chromate treated layer and a silane coupling treated layer are disposed between the ultra-thin copper layer on at least one of both surfaces and the surface treated layer.

In yet another embodiment of the copper foil with a carrier according to the present invention, if the ultra-thin copper layer is disposed on one surface of the carrier in the copper foil with a carrier, one or more layers selected from the group consisting of a chromate treated layer and a silane coupling treated layer are disposed on the surface of the surface treated layer,

or if the ultra-thin copper layer is disposed on both surfaces of the carrier in the copper foil with a carrier and the surface treated layer is disposed on the ultra-thin copper layer on at least one of both surfaces, one or more layers selected from the group consisting of a chromate treated layer and a silane coupling treated layer are disposed on the surface of the surface treated layer on the ultra-thin copper layer on at least one of both surfaces.

In yet another embodiment of the copper foil with a carrier according to the present invention, in the one or more layers selected from the group consisting of a chromate treated layer and a silane coupling treated layer, a chromate treated layer and a silane coupling treated layer are disposed in this order on the surface of the surface treated layer.

In yet another embodiment of the copper foil with a carrier according to the present invention, the surface treated layer includes a resin layer thereon.

In yet another embodiment of the copper foil with a carrier according to the present invention, the one or more layers selected from the group consisting of a chromate treated layer and a silane coupling treated layer include a resin layer thereon.

In yet another embodiment of the copper foil with a carrier according to the present invention, the surface of the carrier includes a silane coupling treated layer.

Another aspect according to the present invention is a laminate including the copper foil with a carrier according to the present invention.

Further another aspect according to the present invention is a laminate including the copper foil with a carrier according to the present invention and a resin, wherein end surfaces of the copper foil with a carrier are partially or completely covered with the resin.

Further another aspect according to the present invention is a laminate including two copper foils with a carrier according to the present invention and a resin, and the two copper foils with a carrier are disposed in the resin such that the surface close to the ultra-thin copper layer of one of the copper foils with a carrier and the surface close to the ultra-thin copper layer of the other copper foil with a carrier are exposed.

Further another aspect according to the present invention is a laminate including two copper foils with a carrier according to the present invention, wherein the carrier or the ultra-thin copper layer of one of the copper foils with a carrier is laminated on the carrier or the ultra-thin copper layer of the other copper foil with a carrier.

Further another aspect according to the present invention is a method of producing a printed wiring board, wherein a printed wiring board is produced using the copper foil with a carrier according to the present invention.

Further another aspect according to the present invention is a method of producing a printed wiring board, comprising:

a step of providing the copper foil with a carrier according to the present invention and an insulating substrate,

a step of laminating the copper foil with a carrier on the insulating substrate,

a step of peeling the carrier of the copper foil with a carrier to form a copper clad laminate board after lamination of the copper foil with a carrier on the insulating substrate, and

a step of forming a circuit by one of a semi-additive process, a subtractive process, a partly additive process, and a modified semi-additive process.

Further another aspect according to the present invention is a method of producing a printed wiring board, comprising:

a step of forming a circuit on the surface close to the ultra-thin copper layer or the carrier of the copper foil with a carrier according to the present invention,

a step of forming a resin layer on the surface close to the ultra-thin copper layer or the carrier of the copper foil with a carrier such that the circuit is embedded,

a step of peeling the carrier or the ultra-thin copper layer after formation of the resin layer, and

a step of removing the ultra-thin copper layer or the carrier after peeling of the carrier or the ultra-thin copper layer to expose the circuit formed on the surface close to the ultra-thin copper layer or the carrier of the copper foil with a carrier and embedded in the resin layer.

One embodiment of the method of producing a printed wiring board according to the present invention comprises:

a step of forming a circuit on the surface close to the ultra-thin copper layer or the carrier of the copper foil with a carrier according to the present invention,

a step of forming a resin layer on the surface close to the ultra-thin copper layer or the carrier of the copper foil with a carrier such that the circuit is embedded,

a step of forming a circuit on the resin layer,

a step of peeling the carrier or the ultra-thin copper layer after formation of the circuit on the resin layer, and

a step of removing the ultra-thin copper layer or the carrier after peeling of the carrier or the ultra-thin copper layer to expose the circuit formed on the surface close to the ultra-thin copper layer or the carrier of the copper foil with a carrier and embedded in the resin layer.

One embodiment of the method of producing a printed wiring board according to the present invention comprises:

a step of laminating the carrier in the copper foil with a carrier according to the present invention on a resin substrate,

a step of forming a circuit on the surface close to the ultra-thin copper layer of the copper foil with a carrier,

a step of forming a resin layer on the surface close to the ultra-thin copper layer of the copper foil with a carrier such that the circuit is embedded,

a step of peeling the carrier after formation of the resin layer, and

a step of removing the ultra-thin copper layer after peeling of the carrier to expose the circuit formed on the surface close to the ultra-thin copper layer of the copper foil with a carrier and embedded in the resin layer.

Another embodiment of the method of producing a printed wiring board according to the present invention comprises:

a step of laminating the carrier in the copper foil with a carrier according to the present invention on a resin substrate,

a step of forming a circuit on the surface close to the ultra-thin copper layer of the copper foil with a carrier,

a step of forming a resin layer on the surface close to the ultra-thin copper layer of the copper foil with a carrier such that the circuit is embedded,

a step of forming a circuit on the resin layer,

a step of peeling the carrier after formation of the circuit on the resin layer, and

a step of removing the ultra-thin copper layer after peeling of the carrier to expose the circuit formed on the surface close to the ultra-thin copper layer of the copper foil with a carrier and embedded in the resin layer.

Further another aspect according to the present invention is a method of producing a printed wiring board, comprising:

a step of laminating the surface close to the ultra-thin copper layer or the carrier of the copper foil with a carrier according to the present invention on a resin substrate,

a step of disposing at least one layer group composed of a resin layer and a circuit on the surface close to the ultra-thin copper layer or the carrier of the copper foil with a carrier opposite to the surface thereof laminated on the resin substrate, and

a step of peeling the carrier or the ultra-thin copper layer from the copper foil with a carrier after formation of the at least one layer group composed of a resin layer and a circuit.

Yet another embodiment of the method of producing a printed wiring board according to the present invention comprises:

a step of laminating the surface close to the carrier of the copper foil with a carrier according to the present invention on a resin substrate,

a step of disposing at least one layer group composed of a resin layer and a circuit on the surface close to the ultra-thin copper layer of the copper foil with a carrier opposite to the surface thereof laminated on the resin substrate, and

a step of peeling the carrier from the copper foil with a carrier after formation of the at least one layer group composed of a resin layer and a circuit.

Further another aspect according to the present invention is a method of producing a printed wiring board, comprising:

a step of disposing at least one layer group composed of a resin layer and a circuit on at least one of both surfaces of the laminate according to the present invention, and

a step of peeling the carrier or the ultra-thin copper layer from the copper foil with a carrier forming the laminate after formation of the at least one layer group composed of a resin layer and a circuit.

Further another aspect according to the present invention is a method of producing an electronic device, wherein the electronic device is produced using a printed wiring board produced by the method according to the present invention.

The present invention can provide a copper foil with a carrier having a small absolute value of the difference in releasing strength between the copper foil with a carrier prepared by laminating and hot-pressing the surface close to an ultra-thin copper layer of the copper foil with a carrier to an insulating substrate and used after the carrier is peeled off and the copper foil with a carrier prepared by laminating and hot-pressing the surface close to the carrier of the copper foil with a carrier to an insulating substrate and used after the ultra-thin copper layer is peeled off, while generation of swelling during laminating of the copper foil with a carrier to the insulating substrate by hot pressing is prevented, discoloring of the surface of the ultra-thin copper layer due to oxidation is preferably prevented, and the circuit formability is high.

### BRIEF DESCRIPTION OF THE DRAWING

FIG. 1 is a schematic view of the top surface of a circuit for illustrating a method of evaluating circuit formability used in Examples.

### DETAILED DESCRIPTION OF THE PREFERRED EMBODIMENTS

### Copper Foil with Carrier

The copper foil with a carrier according to the present invention includes a carrier, an intermediate layer, an ultra-thin copper layer, and a surface treated layer in this order. The copper foil with a carrier can be used according to a known method of using a copper foil with a carrier. For example, the surface of the surface treated layer on the ultra-thin copper layer or the carrier is laminated and hot-pressed to an insulating substrate composed of a paper-based phenol resin, a paper-based epoxy resin, a synthetic fiber cloth-based epoxy resin, a glass cloth/paper composite based epoxy resin, a glass cloth/glass non-woven fabric composite based epoxy resin, a glass cloth-based epoxy resin, a polyester film, or a polyimide film. The ultra-thin copper layer or the carrier is then peeled, and the ultra-thin copper layer or the carrier is etched into a target conductive pattern. A final printed wiring board can be thereby produced.

The copper foil with a carrier according to the present invention does not have a roughened layer on the surface of the ultra-thin copper layer. The surface treated layer consists of Zn or a Zn alloy. The amount of Zn applied in the surface treated layer is 30 to 300 μg/dm². Formation of the surface treated layer with Zn or a Zn alloy on the surface of the ultra-thin copper layer without any roughened layer and control of the amount of Zn applied in the surface treated layer to 30 to 300 μg/dm² can prevent and reduce the difference between releasing strength A of the carrier when the surface close to the ultra-thin copper layer of the copper foil with a carrier is laminated and hot-pressed to an insulating substrate and the copper foil with a carrier is used after the carrier is peeled off and releasing strength B of the ultra-thin copper layer when the surface close to the carrier of the copper foil with a carrier is laminated and hot-pressed to an insulating substrate and the copper foil with a carrier is used after the ultra-thin copper layer is peeled off, and thus reduce the difference in releasing strength. In the copper foil with a carrier according to the present invention, (the absolute value of) the difference between the releasing strength when the surface close to the ultra-thin copper layer of the copper foil with a carrier is laminated and hot-pressed to an insulating substrate and the copper foil with a carrier is used after the carrier is peeled off and the releasing strength when the surface close to the carrier of the copper foil with a carrier is laminated and hot-pressed to an insulating substrate and the copper foil with a carrier is used after the ultra-thin copper layer is peeled off can be prevented to 25 gf/cm or less, preferably 20 gf/cm or less, more preferably 10 gf/cm or less, more preferably 5 gf/cm or less. Two or more surface treated layers may be disposed. The Zn alloy for the surface treated layer may contain Zn and one or more elements selected from the group consisting of Ni, Co, Cu, Mo, and Mn. The Zn alloy for the surface treated layer may be composed of Zn and one or more elements selected from the group consisting of Ni, Co, Cu, Mo, and Mn. The surface treated layer may be composed of a Zn alloy composed of Zn and one or more elements selected from the group consisting of Co and Ni. The surface treated layer may be composed of a Zn alloy consisting of Zn and Co. The surface treated layer may be composed of a Zn alloy consisting of Zn and Ni.

In the surface treated layer composed of a Zn alloy consisting of Zn and Ni, the proportion (% by mass) of Zn in the surface treated layer [=amount (μg/dm²) of Zn applied/{amount (μg/dm²) of Zn applied+amount (μg/dm²) of Ni applied}×100] is controlled to 51% by mass or more. A proportion of Zn in the surface treated layer controlled to as high as 51% by mass or more prevents a reduction in circuit formability by Ni, and enhances circuit formability. The upper limit value of the proportion (% by mass) of Zn in the surface treated layer is preferably less than 100% by mass, more preferably 99.9% by mass or less, still more preferably 99% by mass or less, still more preferably 98% by mass or less, still more preferably 97% by mass or less, still more preferably 95% by mass or less, still more preferably 85% by mass or less, still more preferably 65% by mass or less, still more preferably 60% by mass or less, still more preferably 55% by mass or less. The proportion (% by mass) of Zn in the surface treated layer is preferably 51% by mass or more and less than 100% by mass, more preferably 52 to 97% by mass, still more preferably 55 to 97% by mass, still more preferably 60 to 95% by mass. A proportion of Zn controlled to less than 100% can reduce possibilities of eluting chemicals between the resin and the ultra-thin copper layer to enhance the resistance against chemicals of the laminate of the resin and the ultra-thin copper layer when the laminate is immersed in chemicals, for example.

Unlike the present invention, any roughened layer disposed on the surface of the ultra-thin copper layer may lead to difficulties in controlling the releasing strength between the ultra-thin copper layer and the carrier, and thus destabilization of the releasing strength. The releasing strength may be significantly different or uneven in the case where the surface close to the ultra-thin copper layer of the copper foil with a carrier is laminated and hot-pressed to an insulating substrate and the copper foil with a carrier is used after the carrier is peeled off and the case where the surface close to the carrier of the copper foil with a carrier is laminated and hot-pressed to an insulating substrate and the copper foil with a carrier is used after the ultra-thin copper layer is peeled off. The roughened layer indicates a plated layer formed through roughening plating (roughening by plating) with copper plating.

In the copper foil with a carrier according to the present invention, the surface close to the ultra-thin copper layer of the copper foil with a carrier and/or the surface close to the carrier of the copper foil with a carrier preferably has a surface roughness Rz (ten-point height of irregularities Rz (JIS B0601 1994) of 0.1 to 2.0 μm. If the surface close to the ultra-thin copper layer of the copper foil with a carrier and/or the surface close to the carrier of the copper foil with a carrier has a surface roughness Rz of less than 0.1 μm, the surface close to the ultra-thin copper layer of the copper foil with a carrier and/or the surface close to the carrier of the copper foil with a carrier may not be laminated and hot-pressed to the insulating substrate with sufficient adhesion. If the surface close to the ultra-thin copper layer of the copper foil with a carrier and/or the surface close to the carrier of the copper foil with a carrier has a surface roughness Rz of more than 2.0 μm, etching residues may be readily generated during formation of wiring by etching of the ultra-thin copper layer and/or the carrier to reduce microwiring formability. In the copper foil with a carrier according to the present invention, the surface close to the ultra-thin copper layer of the copper foil with a carrier has a surface roughness Rz of more preferably 0.2 to 1.8 μm, still more preferably 0.2 to 1.5 μm, still more preferably 0.3 to 1.0 μm.

The surface roughness Rz of the surface close to the ultra-thin copper layer of the copper foil with a carrier can be controlled through control of the surface roughness Rz of the surface close to the ultra-thin copper layer of the carrier or through control of the composition of the plating solution used in formation of the ultra-thin copper layer (for example, addition of a gloss agent).

The surface roughness Rz of the surface close to the carrier of the copper foil with a carrier can be controlled through chemical polishing such as etching of the surface of the carrier or mechanical polishing such as shot blasting and buffing. If the carrier is an electrolytic metal foil, the surface roughness Rz can be controlled through control of the composition of the plating solution used in production of the carrier or control of the surface roughness of the electrolysis drum. If the carrier is a rolled metal foil, the surface roughness Rz can be controlled through control of the surface roughness of a rolling roll.

### <Carrier>

The carrier usable in the present invention is a metal foil or a resin film. In use of a metal foil as the carrier, the carrier is provided in the form of a copper foil, a copper alloy foil, a nickel foil, a nickel alloy foil, an iron foil, an iron alloy foil, a stainless steel foil, an aluminum foil, or an aluminum alloy foil, for example. In use of a resin film as the carrier, the carrier is provided in the form of a polyimide film, an insulating resin film, a liquid crystal polymer (LCP) film, a PET film, a fluorinated resin film, a polyamide film, a polyethylene terephthalate (PET) film, a polypropylene (PP) film, or a polyamideimide film, for example.

The carrier usable in the present invention is typically provided in the form of a rolled copper foil or an electrodeposited copper foil. Usually, the electrodeposited copper foil is produced as follows: Copper is deposited on a drum of titanium or stainless steel in a copper sulfate plating bath by electrolysis. The rolled copper foil is produced through repeated plastic forming with a rolling roll and heat treatment. Examples of usable materials for the copper foil include high purity copper such as tough-pitch copper (JIS H3100 alloy No. C1100) and oxygen-free copper (JIS H3100 alloy No. C1020 or JIS H3510 alloy No. C1011), and copper alloys such as Sn containing copper, Ag containing copper, copper alloys containing Cr, Zr, or Mg, and Corson copper alloys containing Ni and Si. Through the specification, the term “copper foil” used alone includes copper alloy foils.

The carrier usable in the present invention has any thickness. The thickness may be appropriately adjusted to serve as a carrier, for example, 5 μm or more. An excessively large thickness increases production cost. The thickness is preferably 500 μm or less in general. The thickness of the carrier is typically 8 to 70 μm, more typically 12 to 70 μm, more typically 18 to 35 μm. The carrier preferably has a small thickness to reduce cost of raw materials. For this reason, the thickness of the carrier is typically 5 μm or more and 35 μm or less, preferably 5 μm or more and 18 μm or less, preferably 5 μm or more and 12 μm or less, preferably 5 μm or more and 11 μm or less, preferably 5 μm or more and 10 μm or less. A carrier having a small thickness readily bends and wrinkles during feeding of the carrier. For example, a smooth conveying roll for an apparatus for producing a copper foil with a carrier and a short distance between the conveying roll and the following conveying roll are effective in preventing bend and wrinkle. If the copper foil with a carrier is used in one of methods of producing a printed wiring board, i.e., an embedded process, the carrier should have high rigidity. For this reason, in the embedded process, the carrier has a thickness of preferably 18 μm or more and 300 μm or less, preferably 25 μm or more and 150 μm or less, preferably 35 μm or more and 100 μm or less, more preferably 35 μm or more and 70 μm or less.

A roughened layer may be disposed on the surface of the carrier opposite to the surface for the ultra-thin copper layer to be disposed. The roughened layer may be disposed by a known method, or may be disposed by a roughening treatment described later. A roughened layer disposed on the surface of the carrier opposite to the surface for the ultra-thin copper layer to be disposed is advantageous in that peeling of the carrier and the resin substrate is prevented through lamination of the roughened layer of the carrier on a support such as a resin substrate.

The carrier according to the present invention can be prepared on the following conditions on preparation of an electrodeposited copper foil. The rest of the treatment solution used in electrolysis, surface treatment, or plating used in the present invention is water, unless otherwise specified.

### <Electrodeposited Copper Foil (Normal)>

### <Electrolyte Solution Composition>

Copper: 80 to 110 g/L

Sulfuric acid: 70 to 110 g/L

Chlorine: 10 to 100 mass ppm

Glue: 0.01 to 15 mass ppm, preferably 1 to 10 mass ppm (chlorine is unnecessary at a glue content of 5 mass ppm or more)

### <Electrodeposited Copper Foil (Flat Double-Sided)>

### <Electrolyte Solution Composition>

Copper: 90 to 110 g/L

Sulfuric acid: 90 to 110 g/L

Chlorine: 50 to 100 mg/L

Leveling agent 1 (bis(3-sulfopropyl)disulfide): 10 to 50 mg/L

Leveling agent 2 (dialkylamino group containing polymer): 10 to 50 mg/L

Examples of the dialkylamino group containing polymer usable include a dialkylamino group containing polymer represented by the following formula:

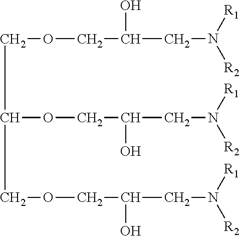

where R₁ and R₂ represent a group selected from the group consisting of a hydroxyalkyl group, an ether group, an aryl group, an aromatic substituted alkyl group, an unsaturated hydrocarbon group, and an alkyl group.

### <Electrodeposited Copper Foil (Normal) and Electrodeposited Copper Foil (Flat Double-Sided)>

### <Conditions on Production>

Current density: 50 to 200 A/dm²

Temperature of electrolyte solution: 40 to 70° C.

Linear velocity of electrolyte solution: 3 to 5 m/sec

Electrolysis time: 0.5 to 10 minutes

### <Intermediate Layer>

An intermediate layer is disposed on one or both surfaces of the carrier. An additional layer may be disposed between the carrier and the intermediate layer. Any intermediate layer can be used in the present invention as long as the intermediate layer prevents peeling of the ultra-thin copper layer from the carrier before lamination of the copper foil with a carrier on an insulating substrate while enabling peeling of the ultra-thin copper layer from the carrier after lamination of the copper foil with a carrier on the insulating substrate. For example, the intermediate layer in the copper foil with a carrier according to the present invention may contain one or two or more selected from the group consisting of Cr, Ni, Co, Fe, Mo, Ti, W, P, Cu, Al, and Zn, alloys thereof, hydrates thereof, oxides thereof, and organic products thereof. The intermediate layer may be composed of a plurality of sublayers.

For example, the intermediate layer can be formed as follows: A layer is formed on the carrier, the layer being a metal monolayer consisting of one element selected from the group consisting of Cr, Ni, Co, Fe, Mo, Ti, W, P, Cu, Al, and Zn, or an alloy layer containing or consisting of one or two or more elements selected from the group consisting of Cr, Ni, Co, Fe, Mo, Ti, W, P, Cu, Al, and Zn. A layer consisting of a hydrate, an oxide, or an organic product of one or two or more elements selected from the group consisting of Cr, Ni, Co, Fe, Mo, Ti, W, P, Cu, Al, and Zn is formed on the layer.

For example, the intermediate layer can be formed as follows: A layer is formed on the carrier, the layer being a metal monolayer consisting of one element selected from the group consisting of Cr, Ni, Co, Fe, Mo, Ti, W, P, Cu, Al, and Zn, or two or more alloy layers containing or consisting of one or two or more elements selected from the group consisting of Cr, Ni, Co, Fe, Mo, Ti, W, P, Cu, Al, and Zn.

For example, the intermediate layer can be formed as follows: An organic product layer is formed on the carrier, and a layer is formed on the organic product layer, the layer being a metal monolayer consisting of one element selected from the group consisting of Cr, Ni, Co, Fe, Mo, Ti, W, P, Cu, Al, and Zn, or an alloy layer containing or consisting of one or two or more elements selected from the group consisting of Cr, Ni, Co, Fe, Mo, Ti, W, P, Cu, Al, and Zn.

If the intermediate layer is disposed only on one surface of the carrier, an anti-corrosive layer such as a Ni-plated layer is preferably disposed on the other surface of the carrier. If the intermediate layer is disposed by a chromate treatment, a zinc chromate treatment, or plating, it is considered that part of the metal deposited, such as chromium or zinc, may be a hydrate or an oxide thereof.

For example, the intermediate layer can be composed of nickel, a nickel-phosphorus alloy, or a nickel-cobalt alloy and chromium laminated on the carrier in this order. The adhesive force between nickel and copper is greater than that between chromium and copper. As a result, the ultra-thin copper layer is peeled at the interface between the ultra-thin copper layer and chromium. A barrier effect of nickel in the intermediate layer is expected to prevent diffusion of the copper component from the carrier to the ultra-thin copper layer. The amount of nickel applied in the intermediate layer is preferably 100 μg/dm² or more and 40000 μg/dm² or less, more preferably 100 μg/dm² or more and 4000 μg/dm² or less, more preferably 100 μg/dm² or more and 2500 μg/dm² or less, more preferably 100 μg/dm² or more and less than 1000 μg/dm². The amount of chromium applied in the intermediate layer is preferably 5 μg/dm² or more and 100 μg/dm² or less. If the intermediate layer is disposed only on one surface of the carrier, an anti-corrosive layer such as a Ni-plated layer is preferably disposed on the other surface of the carrier.

If the intermediate layer contains one or more of molybdenum, cobalt, and tungsten, the amounts of these elements applied are 5 μg/dm² or more, preferably 50 μg/dm² or more. To attain high releasing properties between the carrier and the ultra-thin copper layer, the amounts of these elements applied are preferably 3000 μg/dm² or less, 2000 μg/dm² or less, 1000 μg/dm² or less.

A preferred organic product contained in the intermediate layer consists of one or two or more selected from the nitrogen containing organic compounds, sulfur containing organic compounds, and carboxylic acids. Among these nitrogen containing organic compounds, sulfur containing organic compounds, and carboxylic acids, the nitrogen containing organic compounds include nitrogen containing organic compounds having substituents. Specific examples of nitrogen containing organic compounds preferably used include triazole compounds having substituents, such as 1,2,3-benzotriazole, carboxybenzotriazole, N′,N′-bis(benzotriazolylmethyl)urea, 1H-1,2,4-triazole, and 3-amino-1H-1,2,4-triazole.

Examples of the sulfur containing organic compounds preferably used include mercaptobenzothiazole, thiocyanuric acid, and 2-benzimidazolethiol.

Carboxylic acids particularly preferably used are monocarboxylic acids. Among these monocarboxylic acids, oleic acid, linolic acid, and linoleic acid are preferably used.

The organic product is contained in a thickness of preferably 5 nm or more and 80 nm or less, more preferably 10 nm or more and 70 nm or less.

### <Ultra-Thin Copper Layer>

An ultra-thin copper layer is disposed on the intermediate layer. An additional layer may be disposed between the intermediate layer and the ultra-thin copper layer. The ultra-thin copper layer can be formed through electric plating with an electrolytic bath using copper sulfate, copper pyrophosphate, copper sulfamate, or copper cyanide. A copper sulfate bath is preferred because it is used in preparation of common electrodeposited copper foils and can form copper foils with high current density. The ultra-thin copper layer can have any thickness. The ultra-thin copper layer is usually thinner than the carrier, and has a thickness of 12 μm or less, for example. The thickness is typically 0.01 to 12 μm, more typically 0.05 to 12 μm, more typically 0.1 to 12 μm, more typically 0.15 to 12 μm, more typically 0.2 to 12 μm, more typically 0.3 to 12 μm, more typically 0.5 to 12 μm, more typically 1 to 6 μm, still more typically 1.5 to 5 μm, still more typically 2 to 5 μm. In consideration of readiness in processing of the copper foil with a carrier during production of printed wiring boards, the ultra-thin copper layer has a thickness of preferably 1 to 7 μm, more preferably 1.5 to 6 μm, more preferably 2 to 6 μm, more preferably 2 to 5 μm, more preferably 3 to 5 μm. The ultra-thin copper layer may be disposed on both surfaces of the carrier.

The copper foil with a carrier according to the present invention can be used to prepare a laminate (such as a copper clad laminate). The laminate may be composed of “ultra-thin copper layer/intermediate layer/carrier/resin or prepreg” laminated in this order, “carrier/intermediate layer/ultra-thin copper layer/resin or prepreg” laminated in this order, “ultra-thin copper layer/intermediate layer/carrier/resin or prepreg/carrier/intermediate layer/ultra-thin copper layer” laminated in this order, “carrier/intermediate layer/ultra-thin copper layer/resin or prepreg/ultra-thin copper layer/intermediate layer/carrier” laminated in this order, or “carrier/intermediate layer/ultra-thin copper layer/resin or prepreg/carrier/intermediate layer/ultra-thin copper layer” laminated in this order, for example. The resin or the prepreg may be a resin layer described later, and may contain a resin, a resin curing agent, a compound, a curing accelerator, a dielectric substance, a reaction catalyst, a crosslinking agent, a polymer, a prepreg, and a skeleton material used in the resin layer described later. The copper foil with a carrier may be smaller than the resin or the prepreg seen in planar view.

### <Surface Treated Layer>

The surface treated layer is composed of Zn or a Zn alloy, and the amount of Zn applied in the surface treated layer is controlled to 30 μg/dm² or more. As a result, discoloring of the surface of the ultra-thin copper layer due to oxidation can be preferably prevented. A surface of the ultra-thin copper layer partially discolored due to oxidation may lead to uneven treatments by a variety of surface treatments and etching treatments used during the production process of the printed wiring board. Accordingly, it is important to prevent discoloring of the surface of the ultra-thin copper layer due to oxidation after the copper foil with a carrier is hot-pressed to an insulating substrate. Generation of swelling during laminating of the copper foil with a carrier to the insulating substrate by hot pressing can be preferably prevented through control of the amount of Zn applied in the surface treated layer to 300 μg/dm² or less. Although the reason why swelling is readily generated at an amount of Zn applied exceeding 300 μg/dm² is not always clear, the present inventors infer that Zn in the surface treated layer diffuses through the ultra-thin copper layer to the intermediate layer due to heat generated during hot-pressing to the insulating substrate, reacting with the components in the intermediate layer to generate swelling. The amount of Zn applied in the surface treated layer is preferably 50 to 280 μg/dm², more preferably 80 to 240 μg/dm².

The surface treated layer according to the present invention can also be used as a heat-resistant layer or an anti-corrosive layer.

### <Other Treated Layers>

One or more layers selected from the group consisting of a chromate treated layer and a silane coupling treated layer may be disposed between the ultra-thin copper layer and the surface treated layer. One or more layers selected from the group consisting of a chromate treated layer and a silane coupling treated layer may be disposed on the surface of the surface treated layer. The one or more layers selected from the group consisting of a chromate treated layer and a silane coupling treated layer may be a chromate treated layer and a silane coupling treated layer disposed in this order on the surface of the surface treated layer. A silane coupling treated layer may be disposed on the surface of the carrier. A silane coupling treated layer disposed on the surface of the carrier can enhance the adhesion of the surface close to the carrier of the copper foil with a carrier laminated to the insulating substrate.

The chromate treated layer indicates a layer treated with a solution containing chromic acid anhydride, chromic acid, dichromic acid, chromate, or dichromate. The chromate treated layer may contain an element such as Co, Fe, Ni, Mo, Zn, Ta, Cu, Al, P, W, Sn, As, and Ti (which may have any form such as metal, alloy, oxide, nitride, or sulfide). Specific examples of the chromate treated layer include chromate treated layers treated with an aqueous solution of chromic acid anhydride or potassium dichromate, and chromate treated layers treated with a treatment solution containing chromic acid anhydride or potassium dichromate and zinc.

The silane coupling treated layer may be formed with a known silane coupling agent. Examples of the silane coupling agent include epoxysilane coupling agents, aminosilane coupling agents, methacryloxysilane coupling agents, mercaptosilane coupling agents, vinylsilane coupling agents, imidazolesilane coupling agents, and triazinesilane coupling agents. Two or more silane coupling agents can be used as a mixture. Among these silane coupling agents, aminosilane coupling agents or epoxysilane coupling agents are preferably used in formation of the silane coupling treated layer.

The surface of the ultra-thin copper layer, the heat-resistant layer, the anti-corrosive layer, the silane coupling treated layer, or the chromate treated layer can be subjected to the surface treatment described in WO2008/053878, Japanese Patent Laid-Open No. 2008-111169, Japanese Patent No. 5024930, WO2006/028207, Japanese Patent No. 4828427, WO2006/134868, Japanese Patent No. 5046927, WO2007/105635, Japanese Patent No. 5180815, or Japanese Patent Laid-Open No. 2013-19056.

The copper foil with a carrier may include a resin layer on the surface treated layer. The copper foil with a carrier may include a resin layer on one or more layers selected from the group consisting of a chromate treated layer and a silane coupling treated layer. The resin layer may be an insulating resin layer.

The resin layer may be an adhesive, may be a resin for an adhesive, or may be a semi-cured (stage B) insulating resin layer for an adhesive. The semi-cured (stage B) state of the insulating resin layer includes the state where the surface of the insulating resin layer is not sticky to the touch when touched by the finger, the insulating resin layers can be layered for storage, and the insulating resin layer is cured through a heat treatment,

The resin layer may contain a thermosetting resin, or may be composed of a thermoplastic resin. The resin layer may contain a thermoplastic resin. Suitable examples of the resins include, but should not be limited to, resins containing one or more selected from the group consisting of epoxy resins, polyimide resins, polyfunctional cyanic acid ester compounds, maleimide compounds, poly(vinyl acetal) resins, urethane resins, polyethersulfone resins, aromatic polyamide resins, aromatic polyamide resin polymers, rubber resins, polyamines, aromatic polyamines, polyamideimide resins, rubber-modified epoxy resins, phenoxy resins, carboxyl group-modified acrylonitrile-butadiene resins, poly(phenylene oxide), bismaleimide triazine resins, thermosetting poly(phenylene oxide) resins, cyanate ester resins, anhydrides of carboxylic acids, anhydrides of polyvalent carboxylic acids, linear polymers having crosslinkable functional groups, polyphenylene ether resins, 2,2-bis(4-cyanatophenyl)propane, phosphorus containing phenol compounds, manganese naphthenate, 2,2-bis(4-glycidylphenyl)propane, polyphenylene ether-cyanate resins, siloxane-modified polyamideimide resins, cyano ester resins, phosphazene resins, rubber-modified polyamideimide resins, isoprene, hydrogenated polybutadiene, poly(vinyl butyral), phenoxy resins, polymer epoxy resins, aromatic polyamides, fluorinated resins, bisphenol, block copolymerized polyimide resins, and cyano ester resins.

Any epoxy resin having two or more epoxy groups in the molecule and usable in applications of electrical and electronic materials can be used without limitation. Preferred epoxy resins are those prepared through epoxidation of a compound having two or more glycidyl groups in the molecule. The epoxy resin used can be one or a mixture of two or more selected from the group consisting of bisphenol A epoxy resins, bisphenol F epoxy resins, bisphenol S epoxy resins, bisphenol AD epoxy resins, novolac epoxy resins, cresol novolac epoxy resins, alicyclic epoxy resins, brominated epoxy resins, phenol novolac epoxy resins, naphthalene epoxy resins, brominated bisphenol A epoxy resins, ortho-cresol novolac epoxy resins, rubber-modified bisphenol A epoxy resins, glycidylamine epoxy resins, glycidylamine compounds (such as triglycidyl isocyanurate and N,N-diglycidylaniline), glycidyl ester compounds (such as tetrahydrophthalic acid diglycidyl ester), phosphorus containing epoxy resins, biphenyl epoxy resins, biphenyl novolac epoxy resins, trishydroxyphenylmethane epoxy resins, and tetraphenylethane epoxy resins. Alternatively, hydrogenated or halogenated products of the epoxy resins can be used.

Known epoxy resins containing phosphorus can be used as the phosphorus containing epoxy resins. The phosphorus containing epoxy resins are preferably epoxy resins obtained as derivatives from 9,10-dihydro-9-oxa-10-phosphaphenanthrene 10-oxide having two or more epoxy groups in the molecule, for example.

The resin layer may contain a known resin, a resin curing agent, a compound, a curing accelerator, a dielectric substance (any dielectric substance such as a dielectric substance containing an inorganic compound and/or an organic compound, or a dielectric substance containing a metal oxide may be used), a reaction catalyst, a crosslinking agent, a polymer, a prepreg, and a skeleton material. The resin layer can be formed using any substance (such as a resin, a resin curing agent, a compound, a curing accelerator, a dielectric substance, a reaction catalyst, a crosslinking agent, a polymer, a prepreg, and a skeleton material) and/or any method of forming a resin layer, and any forming apparatus described in WO2008/004399, WO2008/053878, WO2009/084533, Japanese Patent Laid-Open No. 11-5828, Japanese Patent Laid-Open No. 11-140281, Japanese Patent No. 3184485, WO97/02728, Japanese Patent No. 3676375, Japanese Patent Laid-Open No. 2000-43188, Japanese Patent No. 3612594, Japanese Patent Laid-Open No. 2002-179772, Japanese Patent Laid-Open No. 2002-359444, Japanese Patent Laid-Open No. 2003-304068, Japanese Patent No. 3992225, Japanese Patent Laid-Open No. 2003-249739, Japanese Patent No. 4136509, Japanese Patent Laid-Open No. 2004-82687, Japanese Patent No. 4025177, Japanese Patent Laid-Open No. 2004-349654, Japanese Patent No. 4286060, Japanese Patent Laid-Open No. 2005-262506, Japanese Patent No. 4570070, Japanese Patent Laid-Open No. 2005-53218, Japanese Patent No. 3949676, Japanese Patent No. 4178415, WO2004/005588, Japanese Patent Laid-Open No. 2006-257153, Japanese Patent Laid-Open No. 2007-326923, Japanese Patent Laid-Open No. 2008-111169, Japanese Patent No. 5024930, WO2006/028207, Japanese Patent No. 4828427, Japanese Patent Laid-Open No. 2009-67029, WO2006/134868, Japanese Patent No. 5046927, Japanese Patent Laid-Open No. 2009-173017, WO2007/105635, Japanese Patent No. 5180815, WO2008/114858, WO2009/008471, Japanese Patent Laid-Open No. 2011-14727, WO2009/001850, WO2009/145179, WO2011/068157, and Japanese Patent Laid-Open No. 2013-19056, for example.

For example, these resins are dissolved in a solvent such as methyl ethyl ketone (MEK) or toluene to prepare a resin solution. The resin solution is applied onto the ultra-thin copper layer, the heat-resistant layer, the anti-corrosive layer, the chromate coated layer, or the silane coupling agent layer by roll coating. When necessary, the coating is then brought into the stage B state through removal of the solvent by heating and drying. The coating may be dried with a hot air drying furnace. The drying temperature may be 100 to 250° C., preferably 130 to 200° C.

The copper foil with a carrier including the resin layer (resin-coated copper foil with a carrier) is used as follows: The resin layer of a copper foil with a carrier is layered on a base, and then is as a whole hot-pressed to the base to thermally cure the resin layer. The carrier is then peeled to expose the ultra-thin copper layer (the surface close to the intermediate layer of the ultra-thin copper layer should be exposed). A predetermined wiring pattern is formed on the surface of the ultra-thin copper layer.

Use of this resin-coated copper foil with a carrier can reduce the number of prepreg materials used during production of multi-layered printed wiring boards. In addition, the resin layer can have a thickness so as to ensure interlayer insulation. A copper clad laminate board can be produced without any prepreg material. At this time, an insulating resin for an undercoat can also be applied onto the surface of the base to further enhance the smoothness of the surface.

No use of prepreg materials results in a reduction in cost for prepreg materials and a reduction in the number of lamination steps, thus providing economic advantages. Further advantages are that the thickness of the resulting multi-layered printed wiring board can be reduced by the thickness of the prepreg material, thus producing ultra-thin multi-layered printed wiring boards in which a layer has a thickness of 100 μm or less.

The resin layer preferably has a thickness of 0.1 to 80 μm.

A thickness of the resin layer of less than 0.1 μm may reduce the adhesive force. As a result, when such a resin-coated copper foil with a carrier is laminated on a base including an inner layer material without any prepreg material being interposed therebetween, the interlayer insulation between the same and the circuit of the inner layer material cannot be ensured in some cases.

At a thickness of the resin layer of more than 80 μm, a resin layer having a target thickness cannot be formed by a single application step. As a result, extra cost for materials and the extra number of steps should be needed, resulting in economic disadvantages. Furthermore, the resulting resin layer has inferior flexibility. For this reason, crack may be readily generated during handling of the resin layer. An excess resin flow may occur during hot-pressing to the inner layer material to obstruct smooth lamination operation.

The resin-coated copper foil with a carrier can also be produced in another form of a product. Namely, the ultra-thin copper layer, the heat-resistant layer, the anti-corrosive layer, the chromate treated layer, or the silane coupling treated layer can be coated with a resin layer. The resin layer is semi-cured. The carrier is then peeled to produce a resin-coated copper foil without a carrier.

Electronic parts are then mounted on the printed wiring board to finish a printed circuit board. In the present invention, the “printed wiring board” also includes printed wiring boards, printed circuit boards, and printed substrates on which electronic parts are mounted.

Moreover, the printed wiring board may be used to produce electronic devices. The printed circuit boards having electronic parts mounted thereon may be used to produce electronic devices. The printed substrates having electronic parts mounted thereon may be used to produce electronic devices. Examples of the process of producing a printed wiring board using the copper foil with a carrier according to the present invention will now be described.

One embodiment of the method of producing a printed wiring board according to the present invention comprises a step of providing the copper foil with a carrier according to the present invention and an insulating substrate, a step of laminating the copper foil with a carrier on the insulating substrate, a step of, after lamination of the copper foil with a carrier on the insulating substrate so that the ultra-thin copper layer faces the insulating substrate, peeling the carrier of the copper foil with a carrier to form a copper clad laminate board, and a step of forming a circuit by one of a semi-additive process, a modified semi-additive process, a partly additive process, and a subtractive process. An insulating substrate including an internal circuit can also be used.

In the present invention, the semi-additive process indicates a process of slightly applying non-electrolytic plating on an insulating substrate or a copper foil seed layer, forming a pattern, and then forming a conductive pattern by electroplating and etching.

Accordingly, one embodiment of the method of producing a printed wiring board according to the present invention using the semi-additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of completely removing the ultra-thin copper layer exposed after peeling of the carrier by etching using a corrosive solution of an acid or a method using plasma,

a step of disposing through holes or/and blind via holes in the resin exposed after removal of the ultra-thin copper layer by etching,

a step of desmearing a region including the through holes or/and the blind via holes,

a step of disposing a non-electrolytically plated layer in a region including the resin and the through holes or/and the blind via holes,

a step of disposing a plating resist on the non-electrolytically plated layer,

a step of exposing the plating resist to light, and then removing the plating resist in the region in which a circuit is formed,

a step of disposing an electrolytically plated layer in the region from which the plating resist is removed to form a circuit,

a step of removing the plating resist, and a step of removing the non-electrolytically plated layer by flash etching, the non-electrolytically plated layer being in a region other than the region in which a circuit is formed.

Another embodiment of the method of producing a printed wiring board according to the present invention using a semi-additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing through holes or/and blind via holes in the ultra-thin copper layer exposed after peeling of the carrier and in the insulating resin substrate,

a step of desmearing a region including the through holes or/and the blind via holes,

a step of completely removing the ultra-thin copper layer exposed after peeling of the carrier by etching using a corrosive solution of an acid or a method using plasma,

a step of disposing a non-electrolytically plated layer in a region including the resin exposed after removal of the ultra-thin copper layer by etching and the through holes or/and the blind via holes,

a step of disposing a plating resist on the non-electrolytically plated layer,

a step of exposing the plating resist to light, and then removing the plating resist in a region in which a circuit is formed,

a step of disposing an electrolytically plated layer in the region from which the plating resist is removed to form a circuit,

a step of removing the plating resist, and

a step of removing the non-electrolytically plated layer by flash etching, the non-electrolytically plated layer being in a region other than the region in which a circuit is formed.

Another embodiment of the method of producing a printed wiring board according to the present invention using the semi-additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing through holes or/and blind via holes in the ultra-thin copper layer exposed after peeling of the carrier and in the insulating resin substrate,

a step of completely removing the ultra-thin copper layer exposed after peeling of the carrier by etching using a corrosive solution of an acid or a method using plasma,

a step of desmearing a region including the through holes or/and the blind via holes,

a step of disposing a non-electrolytically plated layer in a region including the resin exposed after removal of the ultra-thin copper layer by etching and the through holes or/and the blind via holes,

a step of disposing a plating resist on the non-electrolytically plated layer,

a step of exposing the plating resist to light, and then removing the plating resist in a region in which a circuit is formed,

a step of disposing an electrolytically plated layer in the region from which the plating resist is removed to form a circuit,

a step of removing the plating resist, and

a step of removing the non-electrolytically plated layer by flash etching, the non-electrolytically plated layer being in a region other than the region in which a circuit is formed.

Another embodiment of the method of producing a printed wiring board according to the present invention using the semi-additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of completely removing the ultra-thin copper layer exposed after peeling of the carrier by etching using a corrosive solution of an acid or a method using plasma,

a step of disposing a non-electrolytically plated layer on the surface of the resin exposed after removal of the ultra-thin copper layer by etching,

a step of disposing a plating resist on the non-electrolytically plated layer,

a step of exposing the plating resist to light, and then removing the plating resist in a region in which a circuit is formed,

a step of disposing an electrolytically plated layer in the region from which the plating resist is removed to form a circuit,

a step of removing the plating resist, and

a step of removing the non-electrolytically plated layer and the ultra-thin copper layer by flash etching, the non-electrolytically plated layer and the ultra-thin copper layer being in a region other than the region in which a circuit is formed.

In the present invention, the modified semi-additive process indicates a process of laminating a metal foil on an insulating layer, protecting a non-circuit-forming portion with a plating resist, forming a thick layer of copper on a circuit-forming portion by electrolytic plating, then removing the resist, and removing the metal foil in a portion other than the circuit-forming portion by (flash) etching to form a circuit on the insulating layer.

Accordingly, one embodiment of the method of producing a printed wiring board according to the present invention using the modified semi-additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing through holes or/and blind via holes in the ultra-thin copper layer exposed after peeling of the carrier and in the insulating substrate,

a step of desmearing a region including the through holes or/and the blind via holes,

a step of disposing a non-electrolytically plated layer in the region including the through holes or/and the blind via holes,

a step of disposing a plating resist on the surface of the ultra-thin copper layer exposed after peeling of the carrier,

a step of forming a circuit by electrolytic plating after disposition of the plating resist,

a step of removing the plating resist, and

a step of by flash etching, removing the ultra-thin copper layer exposed after removal of the plating resist.

Another embodiment of the method of producing a printed wiring board according to the present invention using the modified semi-additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing a plating resist on the ultra-thin copper layer exposed after peeling of the carrier,

a step of exposing the plating resist to light, and then removing the plating resist in a region in which a circuit is formed,

a step of disposing an electrolytically plated layer in the region from which the plating resist is removed to form a circuit,

a step of removing the plating resist, and

a step of removing the non-electrolytically plated layer and the ultra-thin copper layer by flash etching, the non-electrolytically plated layer and the ultra-thin copper layer being in a region other than the region in which a circuit is formed.

In the present invention, a partly additive process indicates a process of placing catalyst nuclei on a substrate having a conductor layer disposed thereon, when necessary a substrate having holes for through holes or via holes, etching the substrate to form a conductor circuit, when necessary disposing a solder resist or a plating resist, and then forming a thick layer on the conductor circuit, the through holes, and the via holes by a non-electrolytic plating treatment to produce a printed wiring board.

Accordingly, one embodiment of the method of producing a printed wiring board according to the present invention using the partly additive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing through holes or/and blind via holes in the ultra-thin copper layer exposed after peeling of the carrier and in the insulating substrate,

a step of desmearing a region including the through holes or/and the blind via holes,

a step of placing catalyst nuclei in the region including the through holes or/and the blind via holes,

a step of disposing an etching resist on the surface of the ultra-thin copper layer exposed after peeling of the carrier,

a step of exposing the etching resist to light to form a circuit pattern,

a step of removing the ultra-thin copper layer and the catalyst nuclei by etching using a corrosive solution of an acid or a method using plasma to form a circuit,

a step of removing the etching resist,

a step of disposing a solder resist or a plating resist on the surface of the insulating substrate exposed after removal of the ultra-thin copper layer and the catalyst nuclei by etching using a corrosive solution of an acid or a method using plasma, and

a step of disposing a non-electrolytically plated layer in a region in which the solder resist or the plating resist is not disposed.

In the present invention, the subtractive process indicates a process of selectively removing unnecessary portions of the copper foil on a copper clad laminate board by etching to form a conductive pattern.

Accordingly, one embodiment of the method of producing a printed wiring board according to the present invention using the subtractive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing through holes or/and blind via holes in the ultra-thin copper layer exposed after peeling of the carrier and in the insulating substrate,

a step of desmearing a region including the through holes or/and the blind via holes,

a step of disposing a non-electrolytically plated layer in the region including the through holes or/and the blind via holes,

a step of disposing an electrolytically plated layer on the surface of the non-electrolytically plated layer,

a step of disposing an etching resist on the surface of the electrolytically plated layer or/and the ultra-thin copper layer,

a step of exposing the etching resist to light to form a circuit pattern,

a step of removing the ultra-thin copper layer and the non-electrolytically plated layer and the electrolytically plated layer by etching using a corrosive solution of an acid or by a method using plasma to form a circuit, and

a step of removing the etching resist.

Another embodiment of the method of producing a printed wiring board according to the present invention using the subtractive process comprises:

a step of providing the copper foil with a carrier according to the present invention and an insulating substrate,

a step of laminating the copper foil with a carrier on the insulating substrate,

a step of peeling the carrier of the copper foil with a carrier after lamination of the copper foil with a carrier on the insulating substrate,

a step of disposing through holes or/and blind via holes in the ultra-thin copper layer exposed after peeling of the carrier and in the insulating substrate,

a step of desmearing a region including the through holes or/and the blind via holes,

a step of disposing a non-electrolytically plated layer in the region including the through holes or/and the blind via holes,

a step of forming a mask on the surface of the non-electrolytically plated layer,

a step of disposing an electrolytically plated layer on the surface of the non-electrolytically plated layer in which the mask is not formed,

a step of disposing an etching resist on the surface of the electrolytically plated layer or/and the ultra-thin copper layer,

a step of exposing the etching resist to light to form a circuit pattern,

a step of removing the ultra-thin copper layer and the non-electrolytically plated layer by etching using a corrosive solution of an acid or by a method using plasma to form a circuit, and

a step of removing the etching resist.

A step of disposing through holes or/and blind via holes and the subsequent desmearing step may not be performed.

The method of producing a printed wiring board according to the present invention may comprise a step of forming a circuit on the surface close to the surface treated layer or the carrier of the copper foil with a carrier according to the present invention, a step of forming a resin layer on the surface close to the surface treated layer or the carrier of the copper foil with a carrier such that the circuit is embedded, a step of forming a circuit on the resin layer, a step of peeling the carrier or the ultra-thin copper layer after formation of the circuit on the resin layer, and a step of removing the ultra-thin copper layer or the carrier after peeling of the carrier or the ultra-thin copper layer to expose the circuit formed on the surface close to the surface treated layer or the carrier of the copper foil with a carrier and embedded in the resin layer. The method of producing a printed wiring board may also comprise a step of forming a circuit on the surface close to the surface treated layer or the carrier of the copper foil with a carrier according to the present invention, a step of forming a resin layer on the surface close to the surface treated layer or the carrier of the copper foil with a carrier such that the circuit is embedded, a step of peeling the carrier or the ultra-thin copper layer, and a step of removing the ultra-thin copper layer or the carrier after peeling of the carrier or the ultra-thin copper layer to expose the circuit formed on the surface close to the surface treated layer or the carrier of the copper foil with a carrier and embedded in the resin layer.

A specific example of the method of producing a printed wiring board using the copper foil with a carrier according to the present invention will now be described in detail.

First, a first copper foil with a carrier (first layer) having an ultra-thin copper layer having a surface treated layer formed on the surface thereof is provided. Alternatively, a first copper foil with a carrier (first layer) having a carrier having a surface treated layer formed on the surface thereof may be provided in this step.

Next, a resist is applied onto the surface treated layer of the ultra-thin copper layer, and exposure and development are performed to etch the resist into a predetermined shape. Alternatively, a resist may be applied onto the surface treated layer of the carrier, and exposure and development may be performed to etch the resist into a predetermined shape in this step.

Next, plating is performed for formation of a circuit, and the resist is removed to form a plated circuit of a predetermined shape.

Next, a resin for embedding is disposed on the ultra-thin copper layer such that the plated circuit is covered (such that the plated circuit is embedded), and a resin layer is laminated thereon. The surface treated layer of a second copper foil with a carrier (second layer) is then bonded. Alternatively, in this step, a resin for embedding may be disposed on the carrier such that the plated circuit is covered (such that the plated circuit is embedded), and a resin layer may be laminated thereon. The carrier or the surface treated layer of a second copper foil with a carrier (second layer) may then be bonded.

Next, the carrier is peeled from the second copper foil with a carrier. If the carrier of the second copper foil with a carrier is bonded, the ultra-thin copper layer may be peeled from the second copper foil with a carrier.

Next, predetermined positions of the resin layer are drilled with laser beams to expose the plated circuit and form blind via holes.

Next, copper is buried into the blind via holes to form a buried via fill.

Next, a plated circuit is formed on the via fill.

Next, the carrier is peeled from the first copper foil with a carrier. Alternatively, the ultra-thin copper layer may be peeled from the first copper foil with a carrier in this step.

Next, the ultra-thin copper layer on both surfaces (copper foil when the copper foil is disposed on the second layer, and the carrier when the plated circuit of the first layer is disposed on the surface treated layer of the carrier) is removed by flash etching to expose the surface of the plated circuit under the resin layer.

Next, bumps are formed on the plated circuit exposed from the resin layer, and copper pillars are formed on the solder. A printed wiring board using the copper foil with a carrier according to the present invention is thereby prepared.

In the method of producing a printed wiring board described above, the “ultra-thin copper layer” can be replaced with the carrier and the “carrier” can be replaced with the ultra-thin copper layer. A circuit can be formed on the surface close to the carrier of a copper foil with a carrier, and can be buried with a resin to produce a printed wiring board.

The second copper foil with a carrier (second layer) may be the copper foil with a carrier according to the present invention, may be a conventional copper foil with a carrier, or may be a common copper foil. A mono- or multi-layer of circuit may be further formed on the circuit of the second copper foil with a carrier by one of the semi-additive process, the subtractive process, the partly additive process, and the modified semi-additive process.

Such a method of producing a printed wiring board provides a configuration in which the plated circuit is buried in the resin layer. Such a configuration, for example, enables protection of the plated circuit by the resin layer and thus maintenance of the shape of the circuit during removal of the ultra-thin copper layer by flash etching, and hence facilitates formation of microfine circuits. Protection of the plated circuit by the resin layer enhances migration resistance to preferably prevent electrical conduction of the wiring in the circuit. This facilitates formation of microfine circuits. The surface of the plated circuit exposed after removal of the ultra-thin copper layer by flash etching is depressed from the resin layer. As a result, bumps are readily formed on the plated circuit, and hence copper pillars are readily formed on the bumps, enhancing production efficiency.

Known resins and prepregs can be used as the resin for embedding (resin). For example, a prepreg or a glass cloth impregnated with a bismaleimide triazine (BT) resin or a BT resin, or an ABF film manufactured by Ajinomoto Fine-Techno Co., Inc., or ABF can be used. The resin layer and/or the resin and/or the prepreg described in this specification can also be used as the resin for embedding (resin).

The first copper foil with a carrier used as the first layer may have a substrate or a resin layer on the surface thereof. The first copper foil with a carrier is supported by the substrate or the resin layer to prevent wrinkles, advantageously enhancing productivity. Any substrate or resin layer can be used as long as the substrate or the resin layer can support the first copper foil with a carrier. Examples of usable substrates or resin layers include the carrier, the prepreg, and the resin layer described in this specification, and known carriers, prepregs, resin layers, metal plates, metal foils, inorganic compound plates, inorganic compound foils, organic compound plates, and organic compound foils. Alternatively, a copper foil with a carrier composed of carrier/intermediate layer/ultra-thin copper layer in this order, or composed of ultra-thin copper layer/intermediate layer/carrier in this order may be laminated on both surfaces of a substrate, a resin substrate, a resin, or a prepreg as a core to provide a laminate. The copper foil with a carrier of the laminate may be used as the first copper foil with a carrier, and a circuit may be formed on the surfaces of the copper foils with a carrier of the laminate by the method of producing a printed wiring board described above to produce a printed wiring board. Through the specification, the term “circuit” indicates a concept including wiring.

The method of producing a printed wiring board according to the present invention may be a method of producing a printed wiring board (coreless process), comprising a step of laminating the surface close to the ultra-thin copper layer or the carrier of the copper foil with a carrier according to the present invention on a resin substrate, a step of disposing at least one layer group composed of a resin layer and a circuit on the surface of the copper foil with a carrier opposite to the surface close to the ultra-thin copper layer or the carrier thereof laminated on the resin substrate, and a step of peeling the carrier or the ultra-thin copper layer from the copper foil with a carrier after formation of the at least one layer group composed of a resin layer and a circuit. In the at least one layer group composed of a resin layer and a circuit, the resin layer and the circuit may be disposed in this order or vice versa. In a specific example of the coreless process, first, the surface close to the ultra-thin copper layer or the carrier of one copper foil with a carrier according to the present invention is laminated on a resin substrate to prepare a laminate (also referred to as copper clad laminate board or copper clad laminate). Subsequently, a resin layer is formed on the surface of the copper foil with a carrier opposite to the surface close to the ultra-thin copper layer or the carrier thereof laminated on the resin substrate. The carrier or the ultra-thin copper layer of another copper foil with a carrier may be lamented on the resin layer formed on the surface close to the carrier or the ultra-thin copper layer of the copper foil with a carrier. In the method of producing a printed wiring board (coreless process), a copper foil with a carrier of a laminate having the following configuration may be used: a laminate of carrier/intermediate layer/ultra-thin copper layer in this order or ultra-thin copper layer/intermediate layer/carrier in this order on both surfaces of a resin substrate, a resin, or a prepreg as a core, a laminate of “carrier/intermediate layer/ultra-thin copper layer/resin substrate or resin or prepreg/carrier/intermediate layer/ultra-thin copper layer” in this order on both surfaces of a resin substrate, a resin, or a prepreg as a core, a laminate of “carrier/intermediate layer/ultra-thin copper layer/resin substrate/carrier/intermediate layer/ultra-thin copper layer” in this order on both surfaces of a resin substrate, a resin, or a prepreg as a core, or a laminate of “ultra-thin copper layer/intermediate layer/carrier/resin substrate/carrier/intermediate layer/ultra-thin copper layer” in this order on both surfaces of a resin substrate, a resin, or a prepreg as a core. Another resin layer may be disposed on the exposed surfaces of the ultra-thin copper layers or the carriers on both ends of the laminate. A copper layer or a metal layer may be disposed, and may be then processed to form a circuit or wiring. A different resin layer may be further disposed on the circuit or wiring so as to bury (embed) the circuit or the wiring. Alternatively, a wiring or a circuit of copper or metal may be disposed on the exposed surfaces of the ultra-thin copper layers or the carriers on both ends of the laminate. A different resin layer may be disposed on these wirings or circuits to bury (embed) the wirings or the circuits in the resin. Subsequently, another circuit or wiring and another resin layer may be formed on the different resin layer. Formation of such a circuit or wiring and such a resin layer may be performed more than once (build-up process). The ultra-thin copper layer or the carrier of each copper foil with a carrier in the resulting laminate (hereinafter, also referred to as laminate B) can be peeled from the carrier or the ultra-thin copper layer to prepare a coreless substrate. In preparation of the coreless substrate described above, two copper foils with a carrier may be used to prepare a laminate of ultra-thin copper layer/intermediate layer/carrier/carrier/intermediate layer/ultra-thin copper layer described later, a laminate of carrier/intermediate layer/ultra-thin copper layer/ultra-thin copper layer/intermediate layer/carrier, or a laminate of carrier/intermediate layer/ultra-thin copper layer/carrier/intermediate layer/ultra-thin copper layer, and the laminate can also be used as a core. At least one layer group composed of a resin layer and a circuit can be disposed on the surfaces of the ultra-thin copper layer or the carrier on both ends of the laminate (hereinafter, also referred to as laminate A), and the ultra-thin copper layer or the carrier of each copper foil with a carrier can be then peeled from the carrier or the ultra-thin copper layer to prepare a coreless substrate. In the at least one layer group composed of a resin layer and a circuit, a resin layer and a circuit may be disposed in this order or vice versa. The laminate may have an additional layer on the surface of the ultra-thin copper layer, the surface of the carrier, between the carriers, between the ultra-thin copper layers, or between the ultra-thin copper layer and the carrier. The additional layer may be a resin substrate or a resin layer. Through this specification, the terms “surface of the ultra-thin copper layer,” “surface close to the ultra-thin copper layer,” “ultra-thin copper layer surface,” “surface of the carrier,” “surface close to the carrier,” “carrier surface,” “surface of the laminate,” “laminate surface,” and “surface of the surface treated layer” indicate concepts including the surface (outer surface) of the additional layer when the ultra-thin copper layer, the carrier, the laminate, or the surface treated layer has an additional layer on the surface of the ultra-thin copper layer, the surface of the carrier, the surface of the laminate, or the surface of the surface treated layer, respectively. The laminate preferably has a configuration of ultra-thin copper layer/intermediate layer/carrier/carrier/intermediate layer/ultra-thin copper layer. This is because the ultra-thin copper layer is disposed on the coreless substrate in preparation of a coreless substrate using the laminate; as a result, a circuit is readily formed on the coreless substrate by the modified semi-additive process. The ultra-thin copper layer is readily removed because of its small thickness. As a result, a circuit is readily formed on the coreless substrate by the semi-additive process after removal of the ultra-thin copper layer.

Through this specification, the terms “laminate A,” “laminate B,” and “laminate” without a symbol indicate a laminate including at least laminate A and laminate B.

In the method of producing a coreless substrate, end surfaces of the copper foil with a carrier or the laminate (including laminate A) can be partially or completely covered with a resin to prevent elution of a chemical solution into the intermediate layer or between one copper foil with a carrier and the other copper foil with a carrier forming the laminate during production of the printed wiring board by the build-up process. As a result, separation of the ultra-thin copper layer from the carrier caused by elution of the chemical solution or corrosion of the copper foil with a carrier can be prevented, enhancing the yield. The “resin for partially or completely covering end surfaces of the copper foil with a carrier” or the “resin for partially or completely covering end surfaces of the laminate” used here can be a resin used as the resin layer or a known resin. In the method of producing a coreless substrate, when the copper foil with a carrier or the laminate is seen in planar view, at least part of the outer periphery of the laminated portion of the copper foil with a carrier or the laminate (laminated portion of the carrier and the ultra-thin copper layer or the laminated portion of one copper foil with a carrier and the other copper foil with a carrier) may be covered with a resin or a prepreg. The laminate formed by the method of producing a coreless substrate (laminate A) may be composed of a pair of copper foils with a carrier in separable contact with each other. When the copper foil with a carrier is seen in planar view, the entire outer periphery of the laminated portion of the copper foil with a carrier or the laminate (laminated portion of the carrier and the ultra-thin copper layer or the laminated portion of one copper foil with a carrier and the other copper foil with a carrier) or the entire laminated portion may be covered with a resin or a prepreg. When seen in planar view, the resin or the prepreg is preferably larger than the copper foil with a carrier or the laminate or the laminated portion of the laminate. A preferred laminate has a configuration in which the resin or the prepreg is laminated on both surfaces of the copper foil with a carrier or the laminate to enclose (wrap) the copper foil with a carrier or the laminate with the resin or the prepreg. In such a configuration, the laminated portion of the copper foil with a carrier or the laminate can be covered with the resin or the prepreg when the copper foil with a carrier or the laminate is seen in planar view, preventing crash of other members into the laminated portion from the lateral direction, namely, the direction lateral to the lamination direction. As a result, peeling between the carrier and the ultra-thin copper layer or between the copper foils with a carrier during handling can be reduced. The outer periphery of the laminated portion of the copper foil with a carrier or the laminate is covered with the resin or the prepreg so as not to be exposed. As a result, elution of the chemical solution into the interface of the laminated portion during a treatment with a chemical solution can be prevented, thus preventing corrosion or erosion of the copper foil with a carrier. In separation of one copper foil with a carrier from a pair of the copper foils with a carrier forming the laminate or separation of the carrier from the copper foil (ultra-thin copper layer) of the copper foil with a carrier, the laminated portion may be removed by cutting if the laminated portion of the copper foil with a carrier or the laminate (laminated portion of the carrier and the ultra-thin copper layer or the laminated portion of one copper foil with a carrier and the other copper foil with a carrier) covered with the resin or the prepreg firmly adheres to the resin or the prepreg.

The surface close to the carrier or the ultra-thin copper layer of one copper foil with a carrier according to the present invention may be laminated on the surface close to the carrier or the ultra-thin copper layer of another copper foil with a carrier according to the present invention to form a laminate. Alternatively, the surface close to the carrier or the ultra-thin copper layer of one copper foil with a carrier and the surface close to the carrier or the ultra-thin copper layer of the other copper foil with a carrier may be directly laminated when necessary with an adhesive to form a laminate. The carrier or the ultra-thin copper layer of one copper foil with a carrier and the carrier or the ultra-thin copper layer of the other copper foil with a carrier may be joined. Here, the term “join” includes embodiments in which the carrier and the ultra-thin copper layer are joined to each other through the surface treated layer, if the surface treated layer is included in the carrier or the ultra-thin copper layer. End surfaces of the laminate may be partially or completely covered with a resin.

Carriers, ultra-thin copper layers, a carrier and an ultra-thin copper layer, and copper foils with a carrier can be laminated through simple layering, or by one of the following methods, for example:

(a) metallurgical joining: fusion welding (arc welding, tungsten inert gas (TIG) welding, metal inert gas (MIG) welding, resistance welding, seam welding, spot welding), pressure welding (ultrasonic welding, friction stir welding), brazing and soldering;
(b) mechanical joining: joining with caulking and rivets (joining with self-piercing rivets, joining with rivets), stitcher; and
(c) physical joining: adhesives, (double-sided) adhesive tapes.

Part or all of one carrier can be joined to part or all of the other carrier or part or all of the ultra-thin copper layer by the joining method to laminate the one carrier and the other carrier or the ultra-thin copper layer. A laminate composed of the carriers or the carrier and the ultra-thin copper layer in separable contact with each other can be thereby produced. When one carrier is weakly joined to the other carrier or the ultra-thin copper layer in the laminate of the one carrier and the other carrier or the ultra-thin copper layer, the one carrier is separable from the other carrier or the ultra-thin copper layer without removing the joint portion between the one carrier and the other carrier or the ultra-thin copper layer. When the one carrier is firmly joined to the other carrier or the ultra-thin copper layer, the one carrier can be separated from the other carrier or the ultra-thin copper layer through cutting, chemical polishing (such as etching), or mechanical polishing of the joint portion between the one carrier and the other carrier or the ultra-thin copper layer.

The resulting laminate can be subjected to a step of disposing at least one layer group composed of a resin layer and a circuit, and a step of peeling the ultra-thin copper layer or the carrier from the copper foil with a carrier of the laminate after formation of the at least one layer group composed of a resin layer and a circuit. A printed wiring board having no core can be thereby prepared. The at least one layer group composed of a resin layer and a circuit may be disposed on one or both surfaces of the laminate. In the at least one layer group composed of a resin layer and a circuit, the resin layer and the circuit may be disposed in this order or vice versa.

The resin substrate, the resin layer, the resin, and the prepreg used in the laminate described above may be the resin layer described in this specification, and may contain the resin, the resin curing agent, the compound, the curing accelerator, the dielectric substance, the reaction catalyst, the crosslinking agent, the polymer, the prepreg, and the skeleton material used in the resin layer described in this specification.

The copper foil with a carrier or laminate described above may be smaller than the resin, the prepreg, the resin substrate, or the resin layer when seen in planar view.

### EXAMPLES

The present invention will be now described in more detail by way of Examples of the present invention, but the present invention will not be limited to these Examples.

1. Preparation of Copper Foil with Carrier

### [Carrier]

An electrodeposited copper foil was prepared on the following conditions, and was used as a carrier. The carrier had a thickness of 18 to 300 μm.

### (Conditions on Production of Carriers in Examples and Comparative Examples)

Electrodeposited Copper Foil (Normal)

### <Composition of Electrolyte Solution>

Copper: 80 to 110 g/L

Sulfuric acid: 70 to 110 g/L

Chlorine: 10 to 100 mass ppm

Glue: 0.01 to 15 mass ppm

### <Conditions on Production>

Current density: 50 to 200 A/dm²

Temperature of electrolyte solution: 40 to 70° C.

Linear velocity of electrolyte solution: 3 to 5 m/sec

Electrolysis time: 0.5 to 10 minutes

An increase in the content of glue and/or a reduction in current density can reduce the surface roughness Rz of the electrodeposited copper foil. The surface roughness Rz of the electrodeposited copper foil can be reduced with an electrolysis drum having a surface roughness smaller than those usually used in production of electrodeposited copper foils through polishing of the surface of the electrolysis drum with a polishing brush or a buff.

Electrodeposited Copper Foil (Flat Double-Sided)

### <Composition of Electrolyte Solution>

Copper: 90 to 110 g/L

Sulfuric acid: 90 to 110 g/L

Chlorine: 50 to 100 mg/L

Leveling agent 1 (bis(3-sulfopropyl)disulfide): 10 to 50 mg/L

Leveling agent 2 (dialkylamino group containing polymer): 10 to 50 mg/L

Examples of the dialkylamino group containing polymer usable include a dialkylamino group containing polymer represented by the following formula:

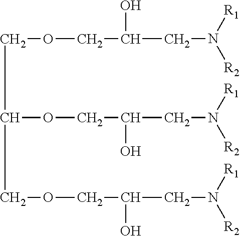

where R₁ and R₂ represent a group selected from the group consisting of a hydroxyalkyl group, an ether group, an aryl group, an aromatic substituted alkyl group, an unsaturated hydrocarbon group, and an alkyl group.

Current density: 50 to 200 A/dm²

Temperature of electrolyte solution: 40 to 70° C.

Linear velocity of electrolyte solution: 3 to 5 m/sec

Electrolysis time: 0.5 to 10 minutes

The surface roughness Rz of the electrodeposited copper foil can be reduced through an increase in content(s) of leveling agent 1 and/or leveling agent 2.

Rolled Copper Foil

A rolled copper foil having a thickness of 18 μm and having a composition of a tough-pitch copper manufactured by JX Nippon Mining & Metals Corporation and specified by JIS H3100 alloy No. C1100.

### [Intermediate Layer]

In Examples and Comparative Examples, the surface of the carrier on which an ultra-thin copper layer was to be disposed was sequentially subjected to a Ni layer forming treatment and an electrolytic chromate treatment to dispose an intermediate layer.

Ni Layer Forming Treatment

The shiny surface of the copper foil was electrically plated on a roll-to-roll continuous plating line on the following conditions to form a Ni layer at an amount of Ni applied of 8000 μg/dm².

### <Composition of Electrolyte Solution>

Nickel sulfate: 270 to 280 g/L

Nickel chloride: 35 to 45 g/L

Nickel acetate: 10 to 20 g/L

Trisodium citrate: 15 to 25 g/L

Gloss agent: saccharin, butynediol, or the like

Sodium dodecyl sulfate: 55 to 75 mass ppm

pH: 4 to 6

### <Conditions on Production>

Temperature of electrolyte solution: 55 to 65° C.

Current density: 7 to 11 A/dm²

Electrolytic Chromate Treatment

After washing with water and washing with an acid, the workpiece was subjected to an electrolytic chromate treatment on the roll-to-roll continuous plating line to apply Cr for a Cr layer onto the Ni layer at an amount of 11 μg/dm² on the following conditions.

### <Composition of Electrolyte Solution>

Potassium bichromate: 1 to 10 g/L

pH: 7 to 10

### <Conditions on Production>

Temperature of electrolyte solution: 40 to 60° C.

Current density: 0.1 to 2.6 A/dm²

Amount of coulomb: 0.5 to 30 As/dm²

### [Ultra-Thin Copper Layer]

The workpiece was electrically plated on the roll-to-roll continuous plating line on the following conditions to form an ultra-thin copper layer having a thickness of 1 to 5 μm on the intermediate layer. A copper foil with a carrier was thereby produced.

Plating bath A

Copper content: 30 to 120 g/L

H₂SO₄ content: 20 to 120 g/L

Plating bath B

Copper: 90 to 110 g/L

H₂SO₄: 90 to 110 g/L

Chlorine: 50 to 100 mg/L

Leveling agent 1 (bis(3-sulfopropyl)disulfide): 10 to 50 mg/L

Leveling agent 2 (dialkylamino group containing polymer): 10 to 50 mg/L

Examples of the dialkylamino group containing polymer usable include a dialkylamino group containing polymer represented by the following formula:

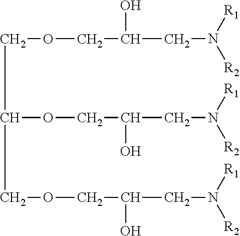

where R₁ and R₂ represent a group selected from the group consisting of a hydroxyalkyl group, an ether group, an aryl group, an aromatic substituted alkyl group, an unsaturated hydrocarbon group, and an alkyl group.

Plating Conditions

Temperature of electrolyte solution: 20 to 80° C.

Current density: 10 to 100 A/dm²

### [Surface Treated Layer]

The surface of the ultra-thin copper layer was sequentially subjected to a surface treatment, an electrolytic chromate treatment, and a silane coupling treatment. The electrolytic chromate treatment and the silane coupling treatment were not performed in Example 11. The electrolytic chromate treatment was not performed in Example 9. The silane coupling treatment was not performed in Example 10.

Surface Treatment

The surface of the ultra-thin copper layer was subjected to the surface treatment on the conditions shown in Table 1 in the Examples and the Comparative Examples.

A roughening treatment was performed before the surface treatment to form a roughened layer in Comparative Example 8. The roughening treatment was performed as roughening plating using a copper plating bath on the plating conditions shown below.

Plating Bath

Cu: 10 g/L

H₂SO₄: 100 g/L

Plating Conditions

Current density: 80 A/dm²

Time: 2 seconds

Solution temperature: 25° C.

Electrolytic Chromate Treatment

### <Composition of Electrolyte Solution>

K₂Cr₂O₇

(Na₂Cr₂O₇ or CrO₃):2 to 10 g/L

NaOH or KOH: 10 to 50 g/L

ZnO or ZnSO₄.7H₂O: 0.05 to 10 g/L

pH: 7 to 13

### <Conditions on Production>

Temperature of electrolyte solution: 20 to 80° C.

Current density: 0.05 to 5 A/dm²

Time: 5 to 30 seconds

Amount of Cr applied: 10 to 150 μg/dm²

Silane Coupling Treatment

### <Composition of Electrolyte Solution>

Aqueous solution of vinyltriethoxysilane

(vinyltriethoxysilane content: 0.1 to 1.4 wt %)

pH: 4 to 5

### <Conditions on Production>

Temperature of electrolyte solution: 25 to 60° C.

Immersion time: 5 to 30 seconds

2. Evaluation of Copper Foil with Carrier
<Measurement of Amounts of Zn and Other Elements Applied onto Surface Close to Ultra-Thin Copper Layer>

The amounts of zinc (Zn) and chromium applied were measured as follows: A sample was dissolved in 7% by mass of hydrochloric acid at a temperature of 100° C., and quantitative analysis by atomic absorption photometry was performed with an atomic absorption photometer (type: AA240FS) manufactured by VARIAN, Inc. The amount of nickel applied was measured as follows: A sample was dissolved with 20% by mass of nitric acid, and was measured with an ICP emission spectrometer (type: SPS3100) manufactured by Seiko Instruments Inc. by ICP emission spectrometry. The amounts of molybdenum and other elements applied were measured as follows: A sample was dissolved in a mixed solution of nitric acid and hydrochloric acid (20% by mass of nitric acid and 12% by mass of hydrochloric acid), and quantitative analysis by atomic absorption photometry was performed with an atomic absorption photometer (type: AA240FS) manufactured by VARIAN, Inc.

The amounts of zinc and other elements applied were measured according to the following procedure. First, the ultra-thin copper layer was peeled from the copper foil with a carrier. If part or all of the intermediate layer did not adhere to the ultra-thin copper layer, the ultra-thin copper layer was then dissolved by the method above, and the amounts of these elements applied were measured by the method above.

If part or all of the intermediate layer adhered to the ultra-thin copper layer after peeling of the ultra-thin copper layer from the copper foil with a carrier, the surfaces other than the surface close to the ultra-thin copper layer of the copper foil with a carrier were masked with a tape having acid resistance, and the unmasked surface close to the ultra-thin copper layer of the copper foil with a carrier was then dissolved by the method above, and the amounts of these elements applied were measured by the method. If the ultra-thin copper layer had a thickness of 1.5 μm or more, the surface close to the ultra-thin copper layer of the copper foil with a carrier was dissolved by a thickness of 0.5 μm from the surface. If the ultra-thin copper layer has a thickness of less than 1.5 μm, the ultra-thin copper layer is dissolved by 30% of the thickness.

If the sample is difficult to dissolve in 20% by mass of nitric acid or 7% by mass of hydrochloric acid used above, the sample is dissolved in a mixed solution of nitric acid and hydrochloric acid (20% by mass of nitric acid and 12% by mass of hydrochloric acid), and the amounts of zinc and other elements applied can be then measured by the method above.

The term “amount of an element applied” indicates the amount (mass) of the element applied per unit area (1 dm²) of a sample.

The proportion of Zn in a Zn alloy was calculated from the following expression:

proportion (%) of Zn=amount (μg/dm²) of Zn applied/[amount (μg/dm²) of Zn applied+total amount (μg/dm²) of elements (excluding Cu) other than Zn applied]×100

If it is difficult to determine whether the component of the sample is a Zn alloy or not, concentration analysis of the elements in the surface close to the ultra-thin copper layer of the copper foil with a carrier is performed in the depth direction with an apparatus enabling concentration analysis of these elements in the depth direction (thickness direction of the ultra-thin copper layer) by a method such as X-ray photoelectron spectroscopy (XPS). If Zn and other elements are detected at positions of the same depth, the component of the sample can be determined as a Zn alloy.

### <Measurement of Thickness of Ultra-Thin Copper Layer>

Measurement of thickness of ultra-thin copper layer by weight method

A copper foil with a carrier is weighed. The ultra-thin copper layer is then peeled. The carrier is weighed. The difference between the weight of the copper foil with a carrier and that of the carrier is defined as the weight of the ultra-thin copper layer.

Size of sample: 10 cm square sheet (punched into a 10 cm square sheet with a press)

Extraction of sample: any three places

In these samples, the thickness of the ultra-thin copper layer was calculated by the weight method from the following expression:

thickness (μm) of ultra-thin copper layer determined by the weight method={(weight (g/100 cm²) of 10 cm square sheet of copper foil with carrier)−(weight (g/100 cm²) of carrier after peeling of ultra-thin copper layer from 10 cm square sheet of copper foil with carrier)}/density (8.96 g/cm³) of copper×0.01(100 cm²/cm²)×10000 μm/cm

The weight of the sample was measured with a precision balance enabling measurement to four decimal places. The resulting weight was used in the calculation above as it was.

The arithmetic average of the three thicknesses of the ultra-thin copper layer determined by the weight method was defined as the thickness of the ultra-thin copper layer determined by the weight method.

The precision balance used was a precision balance IBA-200 from AS ONE Corporation. A press HAP-12 manufactured by Noguchi Press Co., Ltd. was used.

If layers such as the roughened layer, the surface treated layer, the chromate treated layer, and the silane coupling treated layer were formed on the ultra-thin copper layer, the measurement was performed after formation of the layers such as the roughened layer, the surface treated layer, the chromate treated layer, and the silane coupling treated layer. For this reason, in the present invention, the term “thickness of the ultra-thin copper layer” indicates the total thickness of the ultra-thin copper layer and the layers such as the roughened layer, the surface treated layer, the chromate treated layer, and the silane coupling treated layer when these layers such as the roughened layer, the surface treated layer, the chromate treated layer, and the silane coupling treated layer are formed on the ultra-thin copper layer.

<Evaluation of Surface Roughness Rz of Surface Close to Ultra-Thin Copper Layer of Copper Foil with Carrier, Surface Roughness Rz of Surface of Carrier on which Ultra-Thin Copper Layer is to be Disposed, and Surface Roughness Rz of Surface Opposite to Surface of Carrier on which Ultra-Thin Copper Layer is to be Disposed>

After disposition of a predetermined surface treated layer (or after disposition of a chromate treated layer and/or a silane coupling treated layer in a copper foil with a carrier having a chromate treated layer and/or a silane coupling treated layer disposed thereon), the surface roughness Rz of the surface close to the ultra-thin copper layer of the copper foil with a carrier was measured with a laser microscope OLS4000 (LEXT OLS 4000) manufactured by Olympus Corporation according to JIS B0601-1994. The surface roughness Rz was measured at any ten places, and the average of the ten measured values was defined as Rz. The surface roughness Rz of the surface of the carrier on which the ultra-thin copper layer is to be formed, and the surface roughness Rz of the surface opposite to the surface of the carrier on which the ultra-thin copper layer is to be formed were measured by the same method.

The surface roughness Rz was measured as follows: The surface of the ultra-thin copper layer and the carrier was observed at a length for evaluation (reference length) of 257.9 μm and a cut-off value of zero. If the carrier was a rolled copper foil, the surface roughness was measured in a direction (TD) vertical to the rolling direction. If the carrier was an electrodeposited copper foil, the surface roughness was measured in a direction (TD) vertical to the traveling direction of the electrodeposited copper foil in the apparatus for producing an electrodeposited copper foil. The surface roughness Rz was measured in an environment at a temperature of 23 to 25° C.

### <Evaluation of Releasing Strength>

(1) Releasing Strength (A) after Lamination of Ultra-Thin Copper Layer

The surface treated layer of the copper foil with a carrier prepared was laminated to an insulating substrate, and was hot-pressed in vacuum at a pressure of 25 kgf/cm² and a temperature of 220° C. for two hours. The carrier was then pulled with a load cell to measure releasing strength by a 90° releasing method (JIS C 6471 8.1).

(2) Releasing Strength (B) after Lamination of Carrier and Plating of Ultra-Thin Copper Layer

The carrier of the copper foil with a carrier prepared was laminated to an insulating substrate. A copper plating layer was formed on the surface close to the surface treated layer of the copper foil with a carrier such that the total thickness of the ultra-thin copper layer and the copper plating layer was 18 μm. The workpiece was then hot-pressed in vacuum at a pressure of 25 kgf/cm² and a temperature of 220° C. for two hours. The ultra-thin copper layer was then pulled with a load cell to measure releasing strength by 90° releasing method (JIS C 6471 8.1).

### (3) The Absolute Value of the Difference Between the Releasing Strengths Measured (1) and (2) Above was Calculated.

In Table 2, “X-mark” in “Releasing strength (A)” and “Releasing strength (B)” indicates that the carrier or the ultra-thin copper layer could not be peeled from the copper foil with a carrier.

### <Evaluation of Swelling>

The carrier of the copper foil with a carrier prepared was laminated to an insulating substrate, and was hot-pressed in vacuum at a pressure of 20 kgf/cm² and a temperature of 220° C. for two hours. The workpiece was then held in the air at 220° C. for four hours, and was cooled to normal temperature. Subsequently, a region of a 10 cm square was observed with five fields with an optical microscope to count the number of swells on the surface close to the ultra-thin copper layer of the copper foil with a carrier. The number of swells per 10 cm square region was calculated through arithmetic average of the total number of swells observed with five fields.

The swelling was evaluated according to the following criteria:

X-mark: the number of swells per 10 cm square is two or more.

circle: the number of swells per 10 cm square is one or more and less than 2.

circle-circle: the number of swells per 10 cm square is more than 0 and less than 1.

double circle: the number of swells per 10 cm square is 0.

### <Evaluation of Discoloring Due to Oxidation>

The carrier of the copper foil with a carrier prepared was laminated to an insulating substrate, and was hot-pressed in vacuum at a pressure of 20 kgf/cm² and a temperature of 220° C. for two hours. The surface of the ultra-thin copper layer was visually checked to evaluate discoloring due to oxidation. Evaluation was performed according to the following criteria:

X-mark: part of the surface of the ultra-thin copper layer is discolored due to oxidation, and the surface has an uneven color tone.

triangle: the entire surface changes to a brown color tone.

circle: no discoloring due to oxidation is found.

### <Evaluation of Circuit Formability>

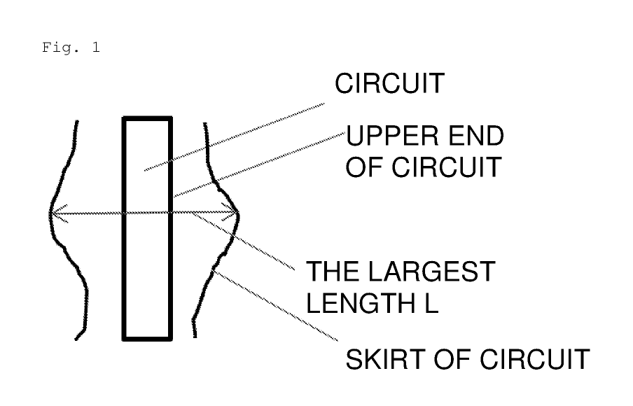

The ultra-thin copper layer of a copper foil with a carrier (copper foil with a carrier after the surface treatment if the ultra-thin copper layer of the copper foil with a carrier was surface treated) was laminated to a bismaleimide triazine resin substrate. The carrier was then peeled to expose the surface of the ultra-thin copper layer. The exposed surface of the ultra-thin copper layer was etched to have a thickness of 2 μm if the thickness of the ultra-thin copper layer was more than 2 μm. The exposed surface of the ultra-thin copper layer was plated with copper if the thickness of the ultra-thin copper layer was less than 2 μm, so that the total thickness of the ultra-thin copper layer and the copper plated layer was 2 μm. In the next step, a patterned copper plated layer having a width of 29 μm was formed at L/S=29 μm/11 μm on the exposed surface of the ultra-thin copper layer (or the surface of the ultra-thin copper layer having a thickness of 2 μm after etching of the exposed surface of the ultra-thin copper layer, or the surface of the ultra-thin copper layer having a total thickness of the ultra-thin copper layer and the copper plated layer of 2 μm after plating with copper of the exposed surface of the ultra-thin copper layer) (total thickness of the ultra-thin copper layer and the patterned copper plated layer: 18.0 μm). The patterned copper plated layer was then subjected to flash etching on the following conditions until the upper end width of the circuit on the copper plated layer reached 20 μm. Thereafter, as shown in FIG. 1, skirts were measured as below by observation of the top surface when seen in planar view. The skirt was composed of residues of copper and/or the surface treated layer projected from the upper end of the circuit having a width of 20 μm of the copper plated layer in a direction orthogonal to the extending direction of the circuit. The largest length L (μm) of the skirt projected from the upper end of the circuit of the copper plated layer in a direction orthogonal to the extending direction of the circuit was measured. Places having skirts were measured in the same manner, and the maximum largest length was used. Observation was performed with an SEM at a magnification of ×1000, and three places in a region of 100 μm×100 μm were observed.

### (Conditions on Etching)

Etching method: spray etching

Spray nozzle: full cone

Spray pressure: 0.10 MPa

Temperature of etching solution: 30° C.

Composition of etching solution:

H₂O₂ 18 g/L

H₂SO₄ 92 g/L

Cu 8 g/L

Additive: a proper amount of FE-830 II W3C manufactured by JCU CORPORATION

the rest: water

Using the obtained largest skirt length L, the etching factor (EF) as an index of circuit formability was calculated from the following expression:

(EF)=2×18/(L−20)

An etching factor of 6 or more indicates that the cross-sectional shape of the circuit is rectangular. Accordingly, it was determined that the circuit formability was high.

The test conditions and the results are shown in Tables 1 and 2.

TABLE 1

| | | Conditions on surface treatment | | | | |
|---|---|---|---|---|---|---|
| | | | | Temperature | | |
| | Components | | pH of | of electrolyte | Current | Electrolysis |
| | of surface | Composition of | electrolyte | solution | density Dk | time |
| | treated layer | electrolyte solution | solution | ° C. | A/dm² | Seconds |
| Example 1 | Zn | Zn: 20 g/L | 3 | 25 | 1 | 0.3 |
| Example 2 | Zn | Zn: 20 g/L | 3 | 25 | 1 | 0.5 |
| Example 3 | Zn | Zn: 20 g/L | 3 | 25 | 1 | 0.4 |
| Example 4 | Zn—Ni | Zn: 20 g/L | 3 | 25 | 2 | 0.4 |
| | | Ni: 5 g/L | | | | |
| Example 5 | Zn—Ni | Zn: 20 g/L | 3 | 25 | 2 | 0.6 |
| | | Ni: 5 g/L | | | | |
| Example 6 | Zn—Ni | Zn: 20 g/L | 3 | 25 | 2 | 0.8 |
| | | Ni: 5 g/L | | | | |
| Example 7 | Zn—Ni | Zn: 20 g/L | 3 | 25 | 2 | 0.8 |
| | | Ni: 5 g/L | | | | |
| Example 8 | Zn—Co—Ni | Zn: 22 g/L | 2 | 40 | 4 | 0.9 |
| | | Co: 1 g/L | | | | |
| | | Ni: 4 g/L | | | | |
| Example 9 | Zn | Zn: 20 g/L | 3 | 25 | 1 | 2.8 |
| Example 10 | Zn | Zn: 20 g/L | 3 | 25 | 1 | 3.0 |
| Example 11 | Zn—Ni | Zn: 20 g/L | 3 | 25 | 2 | 1 |
| | | Ni: 5 g/L | | | | |
| Example 12 | Zn—Fe | Zn: 20 g/L | 2 | 40 | 2 | 0.4 |
| | | Fe: 5 g/L | | | | |
| Example 13 | Zn—Mo | Zn: 20 g/L | 3 | 25 | 2 | 0.4 |
| | | Mo: 5 g/L | | | | |
| Example 14 | Zn—Mn | Zn: 20 g/L | 3 | 25 | 2 | 0.4 |
| | | Mn: 5 g/L | | | | |
| Comparative Example 1 | None | — | — | — | — | — |
| Comparative Example 2 | Zn—Ni | Zn: 20 g/L | 3 | 25 | 0.5 | 0.5 |
| | | Ni: 5 g/L | | | | |
| Comparative Example 3 | Zn—Ni | Zn: 20 g/L | 3 | 25 | 0.5 | 1.3 |
| | | Ni: 5 g/L | | | | |
| Comparative Example 4 | Zn | Zn: 20 g/L | 3 | 25 | 1 | 0.25 |
| Comparative Example 5 | Zn—Ni | Zn: 20 g/L | 3 | 25 | 10 | 0.2 |
| | | Ni: 5 g/L | | | | |
| Comparative Example 6 | Zn | Zn: 20 g/L | 3 | 25 | 1 | 3.2 |
| Comparative Example 7 | Zn | Zn: 20 g/L | 3 | 25 | 1 | 3.1 |
| Comparative Example 8 | Zn—Ni | Zn: 20 g/L | 3 | 25 | 2 | 0.4 |
| | | Ni: 5 g/L | | | | |
| Comparative Example 9 | Zn—Cu | Zn: 20 g/L | 2 | 25 | 2 | 1 |
| | | Cu: 2 g/L | | | | |
| Comparative Example 10 | Zn—Cu—Ni | Zn: 20 g/L | 2 | 40 | 4 | 1 |
| | | Cu: 2 g/L | | | | |
| | | Ni: 5 g/L | | | | |
| Comparative Example 11 | Zn—Co—Ni | Zn: 20 g/L | 2 | 40 | 4 | 1 |
| | | Co: 2 g/L | | | | |
| | | Ni: 5 g/L | | | | |

TABLE 2

| | | | Roughness Rz | Roughness | | |
|---|---|---|---|---|---|---|
| | | | of surface of | Rz of | | |
| | | | carrier opposite to | surface close to | Plating | |
| | | | surface close to | ultra-thin | bath used | Thickness |
| | | Thickness | ultra-thin | copper layer | for forming | of ultra-thin |
| | | of carrier | copper layer | of carrier | ultra-thin | copper layer |
| | Carrier | μm | μm | μm | copper layer | μm |
| Example 1 | Electrodeposited copper foil (normal) | 300 | 2.2 | 1.4 | A | 1 |
| Example 2 | Electrodeposited copper foil (normal) | 18 | 2.2 | 1.4 | A | 2 |
| Example 3 | Electrodeposited copper foil (normal) | 35 | 2.3 | 1.5 | A | 2 |
| Example 4 | Electrodeposited copper foil (normal) | 12 | 2.3 | 1.5 | B | 5 |
| Example 5 | Rolled copper foil | 18 | 0.5 | 0.5 | A | 5 |
| Example 6 | Electrodeposited copper foil (normal) | 18 | 1.7 | 1.1 | B | 5 |
| Example 7 | Electrodeposited copper foil (normal) | 18 | 1.7 | 1.1 | A | 5 |
| Example 8 | Electrodeposited copper foil (flat double-sided) | 18 | 0.8 | 1.2 | B | 5 |
| Example 9 | Electrodeposited copper foil (flat double-sided) | 18 | 0.8 | 1.2 | B | 5 |
| Example 10 | Electrodeposited copper foil (normal) | 18 | 2.3 | 1.5 | A | 2 |
| Example 11 | Electrodeposited copper foil (normal) | 18 | 2.4 | 1.6 | A | 2 |
| Example 12 | Electrodeposited copper foil (normal) | 18 | 2.4 | 1.6 | A | 2 |
| Example 13 | Electrodeposited copper foil (normal) | 12 | 2.3 | 1.5 | B | 5 |
| Example 14 | Electrodeposited copper foil (normal) | 12 | 2.3 | 1.5 | B | 5 |
| Comparative Example 1 | Electrodeposited copper foil (flat double-sided) | 18 | 0.7 | 1.2 | B | 5 |
| Comparative Example 2 | Electrodeposited copper foil (normal) | 18 | 2.3 | 1.6 | A | 2 |
| Comparative Example 3 | Electrodeposited copper foil (normal) | 18 | 2.3 | 1.6 | A | 2 |
| Comparative Example 4 | Electrodeposited copper foil (normal) | 18 | 2.3 | 1.6 | A | 2 |
| Comparative Example 5 | Electrodeposited copper foil (normal) | 18 | 2.5 | 1.7 | A | 2 |
| Comparative Example 6 | Electrodeposited copper foil (normal) | 18 | 2.3 | 1.5 | A | 2 |
| Comparative Example 7 | Electrodeposited copper foil (normal) | 18 | 2.3 | 1.5 | A | 2 |
| Comparative Example 8 | Electrodeposited copper foil (normal) | 18 | 2.3 | 1.5 | B | 5 |
| Comparative Example 9 | Electrodeposited copper foil (flat double-sided) | 18 | 0.6 | 1.0 | B | 5 |
| Comparative Example 10 | Electrodeposited copper foil (normal) | 18 | 2.0 | 1.4 | B | 5 |
| Comparative Example 11 | Electrodeposited copper foil (flat double-sided) | 18 | 0.8 | 1.2 | B | 5 |

| | | | | | | | After |
|---|---|---|---|---|---|---|---|
| | | | | | Rz of | | lamination |
| | | | | | surface close | After | of |
| | | | | | to ultra-thin | lamination of | carrier + |
| | | | | | copper layer | ultra-thin | plating |
| | | Surface | Amount | | of copper | copper layer | Releasing |
| | | treated | of Zn | Proportion | foil with | Releasing | strength |
| | | layer | applied | of Zn | carrier | strength (A) | (B) |
| | Carrier | Components | μg/dm² | wt % | μm | gf/cm | gf/cm |
| Example 1 | Electrodeposited copper foil (normal) | Zn | 30 | 100 | 1.4 | 5 | 22 |
| Example 2 | Electrodeposited copper foil (normal) | Zn | 50 | 100 | 1.4 | 7 | 13 |
| Example 3 | Electrodeposited copper foil (normal) | Zn | 40 | 100 | 1.5 | 6 | 22 |
| Example 4 | Electrodeposited copper foil (normal) | Zn—Ni | 80 | 60 | 1.0 | 4 | 5 |
| Example 5 | Rolled copper foil | Zn—Ni | 120 | 70 | 0.9 | 8 | 12 |
| Example 6 | Electrodeposited copper foil (normal) | Zn—Ni | 180 | 70 | 0.7 | 4 | 4 |
| Example 7 | Electrodeposited copper foil (normal) | Zn—Ni | 180 | 70 | 1.3 | 4 | 4 |
| Example 8 | Electrodeposited copper foil (flat double-sided) | Zn—Co—Ni | 280 | 52 | 0.8 | 28 | 28 |
| Example 9 | Electrodeposited copper foil (flat double-sided) | Zn | 280 | 100 | 0.8 | 28 | 28 |
| Example 10 | Electrodeposited copper foil (normal) | Zn | 300 | 100 | 1.5 | 30 | 30 |
| Example 11 | Electrodeposited copper foil (normal) | Zn—Ni | 240 | 80 | 1.6 | 22 | 14 |
| Example 12 | Electrodeposited copper foil (normal) | Zn—Fe | 120 | 90 | 1.6 | 12 | 10 |
| Example 13 | Electrodeposited copper foil (normal) | Zn—Mo | 80 | 60 | 1.0 | 5 | 6 |
| Example 14 | Electrodeposited copper foil (normal) | Zn—Mn | 80 | 60 | 1.0 | 5 | 6 |
| Comparative Example 1 | Electrodeposited copper foil (flat double-sided) | None | 0 | 0 | 0.8 | 9 | 13 |
| Comparative Example 2 | Electrodeposited copper foil (normal) | Zn—Ni | 10 | 50 | 1.6 | 6 | 10 |
| Comparative Example 3 | Electrodeposited copper foil (normal) | Zn—Ni | 25 | 50 | 1.6 | 5 | 14 |
| Comparative Example 4 | Electrodeposited copper foil (normal) | Zn | 25 | 100 | 1.6 | 5 | 22 |
| Comparative Example 5 | Electrodeposited copper foil (normal) | Zn—Ni | 230 | 30 | 1.7 | 21 | 16 |
| Comparative Example 6 | Electrodeposited copper foil (normal) | Zn | 320 | 100 | 1.5 | X | X |
| Comparative Example 7 | Electrodeposited copper foil (normal) | Zn | 310 | 100 | 1.5 | X | X |
| Comparative Example 8 | Electrodeposited copper foil (normal) | Zn—Ni | 110 | 70 | 2.2 | 35 | X |
| Comparative Example 9 | Electrodeposited copper foil (flat double-sided) | Zn—Cu | 220 | 30 | 0.6 | 20 | 24 |
| Comparative Example 10 | Electrodeposited copper foil (normal) | Zn—Cu—Ni | 200 | 40 | 1.0 | 16 | 18 |
| Comparative Example 11 | Electrodeposited copper foil (flat double-sided) | Zn—Co—Ni | 280 | 50 | 0.8 | 28 | 28 |

| | | | | Discoloring | Circuit |
|---|---|---|---|---|---|
| | | \|(A) − (B)\| | | due to | formability |
| | Carrier | gf/cm | Swelling | oxidation | (EF (—)) |
| Example 1 | Electrodeposited copper foil (normal) | 17 | ⊚ | ◯ | 12 |
| Example 2 | Electrodeposited copper foil (normal) | 7 | ⊚ | ◯ | 12 |
| Example 3 | Electrodeposited copper foil (normal) | 15 | ⊚ | ◯ | 12 |
| Example 4 | Electrodeposited copper foil (normal) | 1 | ⊚ | ◯ | 13 |
| Example 5 | Rolled copper foil | 4 | ⊚ | ◯ | 9 |
| Example 6 | Electrodeposited copper foil (normal) | 1 | ⊚ | ◯ | 12 |
| Example 7 | Electrodeposited copper foil (normal) | 1 | ⊚ | ◯ | 11 |
| Example 8 | Electrodeposited copper foil (flat double-sided) | 0 | ◯◯ | ◯ | 6 |
| Example 9 | Electrodeposited copper foil (flat double-sided) | 0 | ◯◯ | ◯ | 9 |
| Example 10 | Electrodeposited copper foil (normal) | 0 | ◯ | ◯ | 9 |
| Example 11 | Electrodeposited copper foil (normal) | 7 | ⊚ | ◯ | 6 |
| Example 12 | Electrodeposited copper foil (normal) | 2 | ⊚ | ◯ | 9 |
| Example 13 | Electrodeposited copper foil (normal) | 1 | ⊚ | ◯ | 13 |
| Example 14 | Electrodeposited copper foil (normal) | 1 | ⊚ | ◯ | 13 |
| Comparative Example 1 | Electrodeposited copper foil (flat double-sided) | 4 | ⊚ | X | 9 |
| Comparative Example 2 | Electrodeposited copper foil (normal) | 4 | ⊚ | X | 4 |
| Comparative Example 3 | Electrodeposited copper foil (normal) | 9 | ⊚ | X | 4 |
| Comparative Example 4 | Electrodeposited copper foil (normal) | 17 | ⊚ | X | 12 |
| Comparative Example 5 | Electrodeposited copper foil (normal) | 5 | ⊚ | ◯ | 3 |
| Comparative Example 6 | Electrodeposited copper foil (normal) | — | X | ◯ | 9 |
| Comparative Example 7 | Electrodeposited copper foil (normal) | — | X | ◯ | 9 |
| Comparative Example 8 | Electrodeposited copper foil (normal) | — | ⊚ | X | 5 |
| Comparative Example 9 | Electrodeposited copper foil (flat double-sided) | 4 | ⊚ | ◯ | 3 |
| Comparative Example 10 | Electrodeposited copper foil (normal) | 2 | ⊚ | ◯ | 3 |
| Comparative Example 11 | Electrodeposited copper foil (flat double-sided) | 0 | ◯◯ | ◯ | 4 |

### (Results of Evaluation)

In Examples 1 to 14, the releasing strength (A) and the releasing strength (B) were both in the range of 2 to 30 gf/cm, enabling peeling of the ultra-thin copper layer and the carrier. The difference between the releasing strength (A) and the releasing strength (B) was 20 gf/cm or less. Generation of swelling was prevented, no discoloring due to oxidation was found, and circuit formability was high.

In Comparative Example 1 having no surface treated layer, discoloring due to oxidation was generated.

In Comparative Examples 2, 3, and 4, discoloring due to oxidation was generated because of a small amount of Zn applied of 10 μg/dm², 25 μg/dm², and 25 μg/dm², respectively. In Comparative Examples 2, 3, 5, and 9 to 11, the proportion of Zn was low (less than 51% by mass). The circuit formability was poor. In Comparative Example 5, the proportion of Zn was low (30% by mass). The circuit formability was poor.

In Comparative Examples 6 and 7, swelling was generated because of a large amount of Zn applied of 320 μg/dm² and 310 μg/dm², respectively.

In Comparative Example 8, discoloring due to oxidation was generated because the roughened layer was disposed.

What is claimed is:

1. A copper foil with a carrier, comprising a carrier, an intermediate layer, an ultra-thin copper layer, and a surface treated layer in this order,
wherein no roughened layer is disposed on the surface of the ultra-thin copper layer, and
the surface treated layer consists of Zn or a Zn alloy, the amount of Zn applied in the surface treated layer is 30 to 300 μg/dm², and if the surface treated layer is composed of the Zn alloy, the proportion of Zn in the Zn alloy is 51% by mass or more.

2. The copper foil with a carrier according to claim 1,
wherein the Zn alloy comprises Zn and one or more elements selected from the group consisting of Ni, Co, Cu, Mo, and Mn.

3. The copper foil with a carrier according to claim 1,
wherein the Zn alloy consists of Zn and one or more elements selected from the group consisting of Ni, Co, Cu, Mo, and Mn.

4. The copper foil with a carrier according to claim 1,
wherein the surface treated layer is composed of a Zn alloy consisting of Zn and one or more elements selected from the group consisting of Co and Ni, and the proportion of Zn in the surface treated layer is 51% by mass or more and less than 100% by mass.

5. The copper foil with a carrier according to claim 1,
wherein the surface treated layer is composed of a Zn alloy consisting of Zn and Co, and the proportion of Zn in the surface treated layer is 51% by mass or more and less than 100% by mass.

6. The copper foil with a carrier according to claim 1,
wherein the surface treated layer is composed of a Zn alloy consisting of Zn and Ni, and the proportion of Zn in the surface treated layer is 51% by mass or more and less than 100% by mass.

7. The copper foil with a carrier according to claim 1,
wherein the surface close to the ultra-thin copper layer of the copper foil with a carrier has a surface roughness Rz of 0.1 to 2.0 μm.

8. The copper foil with a carrier according to claim 1,
satisfying at least one of the following (A) and (B);
(A) the carrier has a thickness of 5 to 500 μm,
(B) the ultra-thin copper layer has a thickness of 0.01 to 12 μm.

9. The copper foil with a carrier according to claim 1,
wherein if the ultra-thin copper layer is disposed on one surface of the carrier in the copper foil with a carrier, one or more layers selected from the group consisting of a chromate treated layer and a silane coupling treated layer are disposed between the ultra-thin copper layer and the surface treated layer,
or if the ultra-thin copper layer is disposed on both surfaces of the carrier in the copper foil with a carrier and the surface treated layer is disposed on the ultra-thin copper layer on at least one of both surfaces, one or more layers selected from the group consisting of a chromate treated layer and a silane coupling treated layer are disposed between the ultra-thin copper layer on at least one of both surfaces and the surface treated layer.

10. The copper foil with a carrier according to claim 1,
wherein if the ultra-thin copper layer is disposed on one surface of the carrier in the copper foil with a carrier, one or more layers selected from the group consisting of a chromate treated layer and a silane coupling treated layer are disposed on the surface of the surface treated layer,
or if the ultra-thin copper layer is disposed on both surfaces of the carrier in the copper foil with a carrier and the surface treated layer is disposed on the ultra-thin copper layer on at least one of both surfaces, one or more layers selected from the group consisting of a chromate treated layer and a silane coupling treated layer are disposed on the surface of the surface treated layer on the ultra-thin copper layer on at least one of both surfaces.

11. The copper foil with a carrier according to claim 10,
wherein in the one or more layers selected from the group consisting of a chromate treated layer and a silane coupling treated layer, a chromate treated layer and a silane coupling treated layer are disposed in this order on the surface of the surface treated layer.

12. The copper foil with a carrier according to claim 1,
wherein the surface treated layer includes a resin layer thereon.

13. The copper foil with a carrier according to claim 10,
wherein the one or more layers selected from the group consisting of a chromate treated layer and a silane coupling treated layer include a resin layer thereon.

14. The copper foil with a carrier according to claim 1,
wherein the surface of the carrier includes a silane coupling treated layer.

15. A laminate comprising a copper foil with a carrier according to claim 1.

16. A laminate comprising a copper foil with a carrier according to claim 1 and a resin, wherein end surfaces of the copper foil with a carrier are partially or completely covered with the resin.

17. A laminate comprising two copper foils with a carrier according to claim 1 and a resin, wherein the two copper foils with a carrier are disposed in the resin such that the surface close to the ultra-thin copper layer of one of the copper foils with a carrier and the surface close to the ultra-thin copper layer of the other copper foil with a carrier are exposed.

18. A laminate comprising two copper foils with a carrier according to claim 1, wherein the carrier or the ultra-thin copper layer of one of the copper foils with a carrier is laminated on the carrier or the ultra-thin copper layer of the other copper foil with a carrier.

19. A method of producing a printed wiring board, wherein a printed wiring board is produced using a copper foil with a carrier according to claim 1.

20. A method of producing a printed wiring board, comprising:
a step of providing a copper foil with a carrier according to claim 1 and an insulating substrate,
a step of laminating the copper foil with a carrier on the insulating substrate,
a step of peeling the carrier of the copper foil with a carrier to form a copper clad laminate board after lamination of the copper foil with a carrier on the insulating substrate, and
a step of then forming a circuit by one of a semi-additive process, a subtractive process, a partly additive process, and a modified semi-additive process.

21. A method of producing a printed wiring board, comprising:
a step of forming a circuit on the surface close to the ultra-thin copper layer or the carrier of a copper foil with a carrier according to claim 1,
a step of forming a resin layer on the surface close to the ultra-thin copper layer or the carrier of the copper foil with a carrier such that the circuit is embedded,
a step of peeling the carrier or the ultra-thin copper layer after formation of the resin layer, and
a step of removing the ultra-thin copper layer or the carrier after peeling of the carrier or the ultra-thin copper layer to expose the circuit formed on the surface close to the ultra-thin copper layer or the carrier of the copper foil with a carrier and embedded in the resin layer.

22. A method of producing a printed wiring board, comprising:
a step of laminating the surface close to the ultra-thin copper layer or the carrier of a copper foil with a carrier according to claim 1 on a resin substrate,
a step of disposing at least one layer group composed of a resin layer and a circuit on the surface close to the ultra-thin copper layer or the carrier of the copper foil with a carrier opposite to the surface thereof laminated on the resin substrate, and
a step of peeling the carrier or the ultra-thin copper layer from the copper foil with a carrier after formation of the at least one layer group composed of a resin layer and a circuit.

23. A method of producing a printed wiring board, comprising:
a step of disposing at least one layer group composed of a resin layer and a circuit on at least one of both surfaces of a laminate according to claim 15, and
a step of peeling the carrier or the ultra-thin copper layer from the copper foil with a carrier forming the laminate after formation of the at least one layer group composed of a resin layer and a circuit.

24. A method of producing an electronic device, wherein the electronic device is produced using a printed wiring board produced by a method according to claim 19.
